(19) United States
(12) Patent Application Publication
(10) Pub. No.: US 2026/0032926 A1
(43) Pub. Date: Jan. 29, 2026

(54) MICROELECTRONIC DEVICES AND RELATED MEMORY DEVICES

(71) Applicant: Micron Technology, Inc., Boise, ID (US)

(72) Inventor: Fatma Arzum Simsek-Ege, Boise, ID (US)

(21) Appl. No.: 19/251,357

(22) Filed: Jun. 26, 2025

Related U.S. Application Data
(60) Provisional application No. 63/676,276, filed on Jul. 26, 2024.

(51) Int. Cl. H10B 80/00; H01L 23/00; H01L 25/065; H01L 25/18

(52) U.S. Cl. CPC H10B 80/00; H01L 24/08; H01L 25/0657; H01L 25/18; H01L 2224/08145; H01L 2924/1431; H01L 2924/1436

(57) ABSTRACT

A microelectronic device includes a memory array structure, an additional memory array structure, and a control circuitry structure. The memory array structure includes memory cells respectively including a vertical channel access device and a storage node device coupled to the vertical channel access device. The additional memory array structure vertically overlies the memory array structure and includes additional memory cells respectively including an additional vertical channel access device and an additional storage node device coupled to the additional vertical channel access device. The control circuitry structure vertically overlies and is bonded to one or more of the memory array structure and the additional memory array structure. The control circuitry structure includes control logic circuitry coupled to the memory cells of the memory array structure and the additional memory cells of the additional memory array structure. Related memory devices and electronic systems are also described.

### CROSS-REFERENCE TO RELATED APPLICATIONS

This application claims the benefit under 35 U.S.C. § 119(e) of U.S. Provisional Patent Application Ser. No. 63/676,276, filed Jul. 26, 2024, the disclosure of which is hereby incorporated herein in its entirety by this reference.

### TECHNICAL FIELD

The disclosure, in various embodiments, relates generally to the field of microelectronic device design and fabrication. More specifically, the disclosure relates to microelectronic devices including vertical channel access devices, and to related memory devices, electronic systems, and methods.

### BACKGROUND

Microelectronic device designers often desire to increase the level of integration or density of features within a microelectronic device by reducing the dimensions of the individual features and by reducing the separation distance between neighboring features. In addition, microelectronic device designers often desire to design architectures that are not only compact, but offer performance advantages, as well as simplified, easier, and less expensive to fabricate designs.

One example of a microelectronic device is a memory device. Memory devices are generally provided as internal integrated circuits in computers or other electronic devices. There are many types of memory devices including, but not limited to, volatile memory devices. One type of volatile memory device is a dynamic random access memory (DRAM) device. A DRAM device may include a memory array including DRAM cells arranged rows extending in a first horizontal direction and columns extending in a second horizontal direction. In one design configuration, an individual DRAM cell includes an access device (e.g., a transistor) and a storage node device (e.g., a capacitor) electrically connected to the access device. The DRAM cells of a DRAM device are electrically accessible through digit lines and word lines arranged along the rows and columns of the memory array and in electrical communication with control logic devices within a base control logic structure of the DRAM device.

Control logic devices within a base control logic structure underlying a memory array of a DRAM device have been used to control operations on the DRAM cells of the DRAM device. Control logic devices of the base control logic structure can be provided in electrical communication with digit lines and word lines coupled to the DRAM cells by way of routing and contact structures. Unfortunately, processing conditions (e.g., temperatures, pressures, materials) for the formation of the memory array over the base control logic structure can limit the configurations and performance of the control logic devices within the base control logic structure. In addition, the quantities, dimensions, and arrangements of the different control logic devices employed within the base control logic structure can also undesirably impede reductions to the size (e.g., horizontal footprint) of a memory device, and/or improvements in the performance (e.g., faster memory cell ON/OFF speed, lower threshold switching voltage requirements, faster data transfer rates, lower power consumption) of the DRAM device.

### BRIEF DESCRIPTION OF THE DRAWINGS

FIG. 1 is a simplified, partial plan view of a microelectronic device, in accordance with embodiments of the disclosure.

FIG. 2 is a diagram showing different vertical cross-sectional views of a configuration for the microelectronic device shown in FIG. 1, taken about lines A-A and B-B of FIG. 1, in accordance with embodiments of the disclosure.

FIG. 3 is a diagram showing different vertical cross-sectional views of an additional configuration for the microelectronic device shown in FIG. 1, taken about lines A-A and B-B of FIG. 1, in accordance with additional embodiments of the disclosure.

FIG. 4 is a diagram showing different vertical cross-sectional views of a further configuration for the microelectronic device shown in FIG. 1, taken about lines A-A and B-B of FIG. 1, in accordance with further embodiments of the disclosure.

FIG. 5 is a diagram showing different vertical cross-sectional views of another configuration for the microelectronic device shown in FIG. 1, taken about lines A-A and B-B of FIG. 1, in accordance with yet further embodiments of the disclosure.

FIG. 6 is a schematic block diagram of an electronic system, in accordance with embodiments of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. In addition, the description provided below does not form a complete process flow for manufacturing a microelectronic device (e.g., a memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes microelectronic devices exhibiting memory functionality, but not necessarily limited to memory functionality. Stated another way, and by way of non-limiting example only, the term “memory device” includes not only conventional memory (e.g., conventional volatile memory; conventional non-volatile memory), but also includes an application specific integrated circuit (ASIC) (e.g., a system on a chip (SoC)), a microelectronic device combining logic and memory, and a graphics processing unit (GPU) incorporating memory.

As used herein, the term “configured” refers to a size, shape, material composition, orientation, and arrangement of one or more of at least one feature (e.g., material, structure, region, circuit, device) facilitating operation of the at least one feature in a pre-determined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., materials, structures, regions, circuitry, devices) described as “neighboring” one another means and includes features of the disclosed identity (or identities) that are located most proximate (e.g., closest to) one another. Additional features (e.g., additional regions, additional structures, additional regions, additional circuitry, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms “a,” “an,” and “the” are intended to include the plural forms as well, unless the context clearly indicates otherwise.

As used herein, “and/or” includes any and all combinations of one or more of the associated listed items.

As used herein, the phrase “coupled to” refers to structures operatively connected with each other, such as electrically connected through a direct Ohmic connection or through an indirect connection (e.g., by way of another structure).

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively-doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiON₂)), at least one dielectric oxycarbide material (e.g., silicon oxycarbide (SiOₓC_{y})), at least one hydrogenated dielectric oxycarbide material (e.g., hydrogenated silicon oxycarbide (SiCₓO_{y}H_{z})), and at least one dielectric carboxynitride material (e.g., a silicon carboxynitride (SiOₓC_{z}N_{y})). In addition, an “insulative structure” means and includes a structure formed of and including insulative material.

As used herein, the term “semiconductor material” refers to a material having an electrical conductivity between those of insulative materials and conductive materials. For example, a semiconductor material may have an electrical conductivity of between about 10⁻⁸ Siemens per centimeter (S/cm) and about 10⁴S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials. In addition, each of a “semiconductor structure” and a “semiconductive structure” means and includes a structure formed of and including semiconductor material.

Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{y}, SiCₓO_{y}H_{z}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions.

As used herein, the term “homogeneous” means relative amounts of elements included in a feature (e.g., material, region, structure) do not vary throughout different portions (e.g., different horizontal portions, different vertical portions) of the feature. Conversely, as used herein, the term “heterogeneous” means relative amounts of elements included in a feature (e.g., material, region, structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

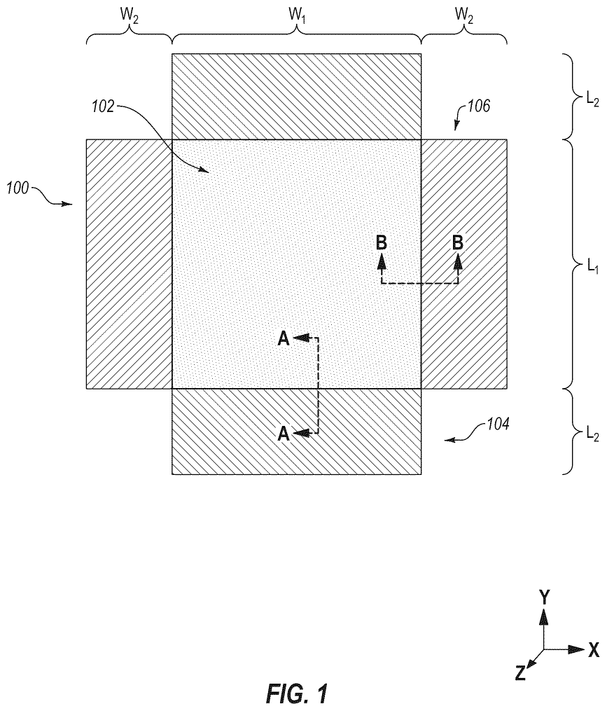

FIG. 1 shows a simplified, partial plan view of a microelectronic device 100 (e.g., a memory device, such as a DRAM device), in accordance with embodiments of the disclosure. As shown in FIG. 1, the microelectronic device 100 may be formed to include an array region 102, digit line (DL) exit regions 104 (also referred to as “digit line (DL) contact socket regions”) horizontally neighboring the array region 102 in a Y-direction (e.g., a first horizontal direction), and word line (WL) exit regions 106 (also referred to as “word line (WL) contact socket regions”) horizontally neighboring the array region 102 in an X-direction (e.g., a second horizontal direction) orthogonal to the Y-direction. The array region 102, the DL exit regions 104, and the WL exit regions 106 are each described in further detail below.

The array region 102 of the microelectronic device 100 is a horizontal area of the microelectronic device 100 configured to have an array of memory cells (e.g., an array of DRAM cells) therein, as described in further detail below. The microelectronic device 100 may include a desired quantity and distribution of array regions 102. For clarity and ease of understanding the drawings and related description, FIG. 1 depicts the microelectronic device 100 as including one (1) array region 102, but the microelectronic device 100 may be formed to include multiple (e.g., more than one (1)) array regions 102 horizontally offset (e.g., in one or more of the X-direction and the Y-direction) from one another. For example, the microelectronic device 100 may include greater than or equal to four (4) array regions 102, greater than or equal to eight (8) array regions 102, greater than or equal to sixteen (16) array regions 102, greater than or equal to thirty-two (32) array regions 102, greater than or equal to sixty-four (64) array regions 102, greater than or equal to one hundred twenty-eight (128) array regions 102, greater than or equal to two hundred fifty-six (256) array regions 102, greater than or equal to five hundred twelve (512) array regions 102, or greater than or equal to one thousand twenty-four (1024) array regions 102.

As shown in FIG. 1, the array region 102 of the microelectronic device 100 may have a first width W₁ in the X-direction and a first length L₁ in the Y-direction orthogonal to the X-direction. In some embodiments, the first width W₁ is substantially equal to the first length L₁. In additional embodiments, the first width W₁ is different than (e.g., greater than, less than) the first length L₁.

The DL exit regions 104 of the microelectronic device 100 may include horizontal areas of the microelectronic device 100 configured to include portions of DL structures (e.g., bit line structures, data line structures) within horizontal areas thereof. For an individual DL exit region 104, at least some DL structures operatively associated with the array region 102 horizontally neighboring the DL exit region 104 in the Y-direction may have portions within the horizontal area of the DL exit region 104. In addition, the DL exit regions 104 may also be configured to include conductive contact structures and conductive routing structures within the horizontal areas thereof that are operatively associated with the DL structures. As described in further detail below, some of the conductive contact structures within the DL exit regions 104 may couple the DL structures to control logic circuitry of control logic devices (e.g., sense amplifier (SA) devices) of the microelectronic device 100. In some embodiments, the DL exit regions 104 respectively horizontally extend in the X-direction. An individual array region 102 may be horizontally interposed between horizontally neighboring DL exit regions 104 in the Y-direction.

As shown in FIG. 1, the DL exit regions 104 of the microelectronic device 100 may respectively have the first width W₁ in the X-direction and a second length L₂ in the Y-direction orthogonal to the X-direction. The second length L₂ of an individual DL exit region 104 is smaller than the first width W₁ of the DL exit region 104. In addition, the second length L₂ of the DL exit region 104 is smaller than the first length L₁ of an individual array region 102 of the microelectronic device 100.

The WL exit regions 106 of the microelectronic device 100 may include additional horizontal areas of the microelectronic device 100 configured to include portions of WL structures (e.g., access line structures) within horizontal boundaries thereof. For an individual WL exit region 106, at least some WL structures operatively associated with the array region 102 horizontally neighboring the WL exit region 106 in the X-direction may have portions within the horizontal area of the WL exit region 106. In addition, the WL exit regions 106 may also be configured to include additional conductive contact structures and additional conductive routing structures within the horizontal areas thereof that are operatively associated with the WL structures. As described in further detail below, some of the additional conductive contact structures within the WL exit regions 106 may couple the WL structures to additional control logic circuitry of additional control logic devices (e.g., sub word line driver (SWD) devices) of the microelectronic device 100. In some embodiments, the WL exit regions 106 respectively horizontally extend in the Y-direction. An individual array region 102 may be horizontally interposed between horizontally neighboring WL exit regions 106 in the X-direction.

As shown in FIG. 1, the WL exit regions 106 of the microelectronic device 100 may respectively have a second width W₂ in the X-direction and the first length L₁ in the Y-direction orthogonal to the X-direction. The second width W₂ of an individual WL exit region 106 is smaller than the first length L₁ of the WL exit region 106. In addition, the second width W₂ of the WL exit region 106 is smaller than the first width W₁ of an individual array region 102 of the microelectronic device 100.

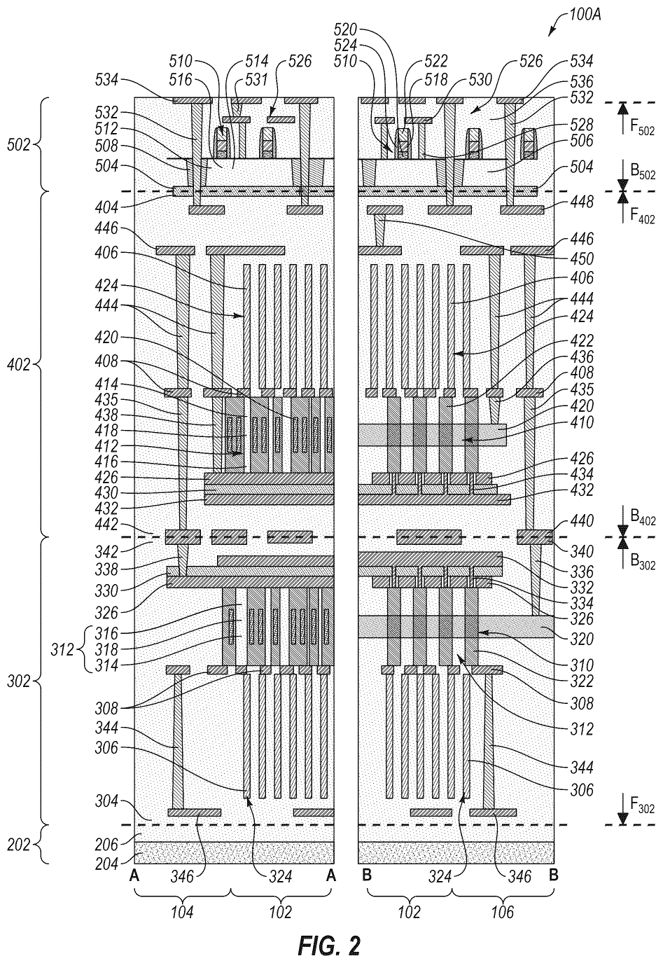

In accordance with embodiments of the disclosure, the microelectronic device 100 may be formed to exhibit different configurations. For example, in accordance with embodiments of the disclosure, FIGS. 2 through 5 are diagrams showing different vertical cross-sectional views for a different configurations for the microelectronic device 100 shown in FIG. 1. In each of FIGS. 2 through 5, the depicted diagram shows different cross-sectional views for a respective configuration for the microelectronic device 100 taken about lines A-A and B-B of FIG. 1. For clarity and ease of understanding the different configurations depicted in FIGS. 2 through 5 and described in further detail below, FIGS. 2 through 5 depict microelectronic devices 100A, 100B, 100C, and 100D, respectively. It will be understood that any of the microelectronic devices 100A, 100B, 100C, and 100D shown in FIGS. 2 through 5 and described in further detail below may be employed as the microelectronic device 100 shown in FIG. 1. Put another way, the microelectronic devices 100A, 100B, 100C, and 100D shown in FIGS. 2 through 5, respectively, represent different potential configurations for the microelectronic device 100 shown in FIG. 1. For each of FIGS. 2 through 5, the vertical cross section taken about line A-A is a view of a YZ-plane of a portion of the microelectronic device 100 (FIG. 1) horizontally overlapping the array region 102 and one of the DL exit regions 104 of the microelectronic device 100 (FIG. 1). In addition, for each of FIGS. 2 through 5, the vertical cross section taken about line B-B is a view of an XZ-plane of an additional portion of the microelectronic device 100 (FIG. 1) overlapping the array region 102 and one of the WL exit regions 106 of the microelectronic device 100 (FIG. 1).

Referring first to FIG. 2, the microelectronic device 100A (and, hence, the microelectronic device 100 (FIG. 1)) may be formed to include a carrier structure 202, a memory array structure 302, an additional memory array structure 402, and a control circuitry structure 502. The memory array structure 302 may vertically overlie and be attached (e.g., bonded) to the carrier structure 202. The additional memory array structure 402 may vertically overlie and be attached (e.g., bonded) to the memory array structure 302. The control circuitry structure 502 may vertically overlie and be attached (e.g., bonded) to the additional memory array structure 402. As shown in FIG. 2, a front side F₃₀₂ (also referred to herein as a “face side”) of the memory array structure 302 may be bonded to the carrier structure 202, a back side B₄₀₂ of the additional memory array structure 402 may be bonded a back side B₃₀₂ of the memory array structure 302, and a back side B₅₀₂ of the control circuitry structure 502 may be bonded to a front side F₄₀₂ of the additional memory array structure 402. Each of the carrier structure 202, the memory array structure 302, the additional memory array structure 402, and the control circuitry structure 502 of the microelectronic device 100A, as well as the relative arrangements thereof, are described in further detail below.

The carrier structure 202 may include a first base structure 204 and a first isolation material 206 in, on, or over the first base structure 204. In some embodiments, the first isolation material 206 is formed on the first base structure 204.

The first base structure 204 of the carrier structure 202 includes a base material or construction upon and/or within which additional features (e.g., materials, structures, regions, circuitry, devices) are formed. The first base structure 204 may be formed of and include one or more of semiconductor material, a base semiconductor material on a supporting structure, glass material (e.g., one or more of borosilicate glass (BSP), phosphosilicate glass (PSG), fluorosilicate glass (FSG), borophosphosilicate glass (BPSG), aluminosilicate glass, an alkaline earth boro-aluminosilicate glass, quartz, titania silicate glass, and soda-lime glass), and ceramic material (e.g., one or more of poly-aluminum nitride (p-AlN), silicon on poly-aluminum nitride (SOPAN), aluminum nitride (AlN), aluminum oxide (e.g., sapphire; α-Al₂O₃), and silicon carbide). By way of non-limiting example, the first base structure 204 may comprise a semiconductor substrate, a glass substrate, or a ceramic substrate. The first base structure 204 may include one or more layers, structures, and/or regions formed therein and/or thereon.

The first isolation material 206 of the carrier structure 202 may be formed of and include at least one insulative material. By way of non-limiting example, the first isolation material 206 may be formed of and include one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, and TiOₓ), at least one dielectric nitride material (e.g., SiN_{y}), at least one dielectric oxynitride material (e.g., SiOₓN_{y}), at least one dielectric carboxynitride material (e.g., SiOₓC_{z}N_{y}), and amorphous carbon. In some embodiments, the first isolation material 206 is formed of and includes SiOₓ (e.g., SiO₂). The first isolation material 206 may be substantially homogeneous, or the first isolation material 206 may be heterogeneous.

The memory array structure 302 may include, without limitation, a group (e.g., an array) of memory cells 324 (e.g., volatile memory cells, such as DRAM cells) for the microelectronic device 100A. The memory cells 324 may respectively be positioned within a horizontal area of the array region 102 of the microelectronic device 100A. As described in further detail below, an individual memory cell 324 of the memory array structure 302 may include a storage node device 306 (e.g., a capacitor) vertically offset from and coupled to a vertical channel (VC) access device 310 (e.g., a vertical channel transistor (VCT)). The memory array structure 302 also includes additional features (e.g., materials, structures, regions, circuitry, devices), as described in further detail below.

The front side F₃₀₂ of the memory array structure 302 may be considered a side (e.g., end surface) most vertically proximate to vertical ends of the storage node device 306 that are most vertically distal from the VC access devices 310. In addition, the back side B₃₀₂ of the memory array structure 302 may be considered an additional side (e.g., additional end surface) most vertically proximate to vertical ends of the VC access devices 310 that are most vertically distal from the storage node device 306. In some embodiments, the front side F₃₀₂ of the memory array structure 302 is positioned relatively vertically closer to the storage node devices 306 of the memory cells 324 than is the back side B₃₀₂ of the memory array structure 302; and the back side B₃₀₂ of the memory array structure 302 is positioned relatively vertically closer to the VC access devices 310 of the memory cells 324 than is the front side F₃₀₂ of the memory array structure 302. As shown in FIG. 2, the storage node devices 306 of the memory cells 324 may be vertically interposed between the front side F₃₀₂ of the memory array structure 302 and the VC access devices 310 of the memory cells 324; and the VC access devices 310 of the memory cells 324 may be vertically interposed between the back side B₃₀₂ of the memory array structure 302 and the storage node devices 306 of the memory cells 324. As described in further detail below, additional features of the memory array structure 302 may be vertically interposed between the front side F₃₀₂ of the memory array structure 302 and the storage node devices 306 of the memory cells 324; and further features of the memory array structure 302 may be vertically interposed between the back side B₃₀₂ of the memory array structure 302 and the VC access devices 310 of the memory cells 324.

For the configuration of the microelectronic device 100A shown in FIG. 2, wherein the front side F₃₀₂ of the memory array structure 302 is attached to the carrier structure 202, a second isolation material 304 of the memory array structure 302 may be bonded (e.g., dielectric-to-dielectric bonded) to the first isolation material 206 of the carrier structure 202. The second isolation material 304 may be formed of and include at least one insulative material. A material composition of the second isolation material 304 may be substantially the same as a material composition of the first isolation material 206; or the material composition of the second isolation material 304 may be different than the material composition of the first isolation material 206. In some embodiments, the second isolation material 304 is formed of and includes dielectric oxide material, such as SiOₓ (e.g., SiO₂). The second isolation material 304 may be substantially homogeneous, or the second isolation material 304 may be heterogeneous.

To attach the front side F₃₀₂ of the memory array structure 302 to the carrier structure 202, the second isolation material 304 of the memory array structure 302 may be provided in physical contact with the first isolation material 206 of the carrier structure 202 at an interface, and then the second isolation material 304 and the first isolation material 206 may be exposed to annealing conditions to form bonds (e.g., dielectric-to-dielectric bonds, such as oxide-to-oxide bonds) between the second isolation material 304 and the first isolation material 206. By way of non-limiting example, the second isolation material 304 and the first isolation material 206 may be exposed to a temperature greater than or equal to about 400° C. (e.g., within a range of from about 400° C. to about 800° C., greater than about 800° C.) to form dielectric-to-dielectric bonds between the second isolation material 304 and the first isolation material 206. In some embodiments, the second isolation material 304 and the first isolation material 206 are exposed to at least one temperature greater than about 800° C. to form oxide-to-oxide bonds between the second isolation material 304 and the first isolation material 206. In FIG. 2, the second isolation material 304 and the first isolation material 206 are distinguished from one another by way of a dashed line representing the interface therebetween prior to bonding. However, the second isolation material 304 and the first isolation material 206 may be integral and continuous with one another following the bonding process. The memory array structure 302 may be attached to the carrier structure 202 without a bond line or with a bond line.

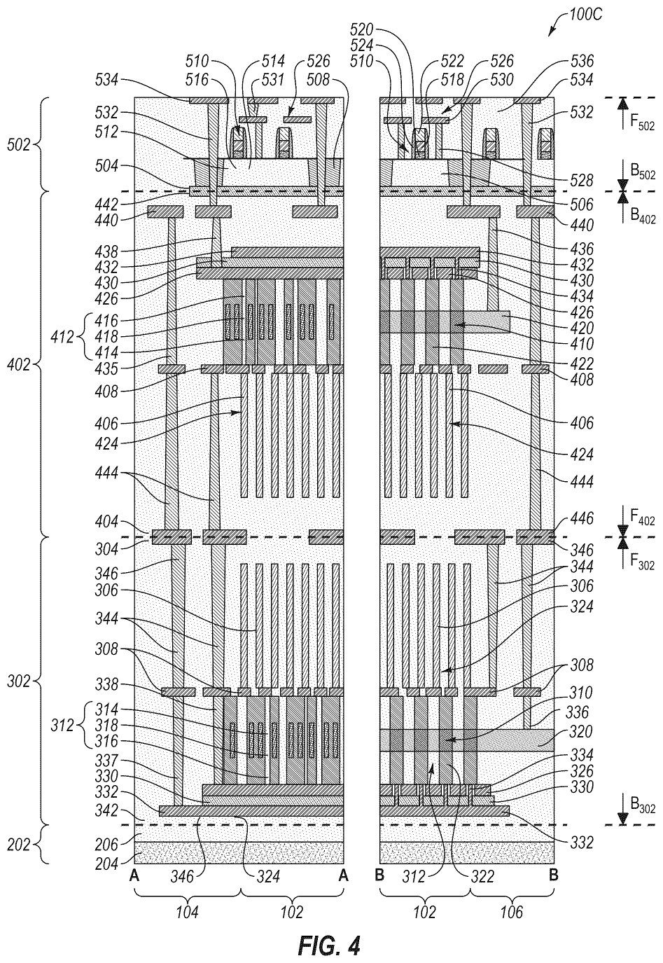

The storage node devices 306 of the memory array structure 302 may be at least partially vertically offset from the second isolation material 304. For example, for the relative orientation of the memory array structure 302 (e.g., relative to the carrier structure 202 and the additional memory array structure 402) shown in FIG. 2, the storage node devices 306 may at least partially vertically overlie the second isolation material 304. However, for a different (e.g., inverted) orientation of the memory array structure 302 (e.g., such as that described below with reference to FIG. 4), the storage node devices 306 may at least partially vertically underlie the second isolation material 304. The storage node devices 306 may individually be formed and configured to store a charge representative of a programmable logic state of the memory cell 324 including the storage node device 306. In some embodiments, the storage node devices 306 are capacitors. During use and operation, a charged capacitor may represent a first logic state, such as a logic 1; and an uncharged capacitor may represent a second logic state, such as a logic 0. Each of the storage node devices 306 may, for example, be formed to include a first electrode (e.g., a bottom electrode), a second electrode (e.g., a top electrode), and a dielectric material between the first electrode and the second electrode.

A redistribution material (RDM) tier (also referred to as “redistribution layer” (RDL) tier) may be vertically offset from the storage node devices 306 and may include RDM structures 308 (also referred to as “RDL structures”). For the relative orientation of the memory array structure 302 depicted in FIG. 2, the RDM structures 308 vertically overlie the storage node devices 306. However, for a different (e.g., inverted) orientation of the memory array structure 302 (e.g., such as that described below with reference to FIG. 4), the RDM structures 308 vertically underlie the storage node devices 306. Within the array region 102, at least some of the RDM structures 308 may, for example, be employed to facilitate a horizontal arrangement (e.g., a hexagonal close packed arrangement) of storage node devices 306 that is different than a horizontal arrangement of the VC access devices 310, while electrically connecting the storage node devices 306 to the VC access devices 310. In addition, within the DL exit region 104 and the WL exit region 106, at least some other of the RDM structures 308 may vertically extend between and couple vertically neighboring conductive contact structures within the DL exit region 104 and the WL exit region 106, as described in further detail below. The RDM structures 308 may individually be formed of and include conductive material. In some embodiments, the RDM structures 308 are individually formed of and include one or more of W, Ru, Mo, and titanium nitride (TiN).

The VC access devices 310 of the memory array structure 302 may be vertically offset from the RDM structures 308. For the relative orientation of the memory array structure 302 depicted in FIG. 2, the VC access devices 310 vertically overlie the RDM structures 308. However, for a different (e.g., inverted) orientation of the memory array structure 302 (e.g., such as that described below with reference to FIG. 4), the VC access devices 310 vertically underlie the RDM structures 308. The VC access devices 310 may individually include a first source/drain region 314, a second source/drain region 316, and a channel region 318 defined within a pillar structure 312; at least one gate structure comprising a portion of at least one of the WL structures 320; and a gate dielectric structure interposed between the channel region 318 thereof and the gate structure thereof.

The pillar structures 312 employed for the VC access devices 310 may respectively be substantially vertically oriented. For example, the pillar structures 312 may individually vertically extend (e.g., in the Z-direction shown in FIG. 1) away from the RDM structures 308 and toward to the back side B₃₀₂ of the memory array structure 302. For an individual pillar structure 312, the channel region 318 may be vertically interposed between the first source/drain region 314 and the second source/drain region 316 thereof. For the relative orientation of the memory array structure 302 depicted in FIG. 2, the channel region 318 may vertically overlie the first source/drain region 314, and the second source/drain region 316 may vertically overlie the channel region 318. However, for a different (e.g., inverted) orientation of the memory array structure 302 (e.g., such as that described below with reference to FIG. 4), the channel region 318 may vertically overlie the second source/drain region 316, and the first source/drain region 314 may vertically overlie the channel region 318.

The pillar structures 312 may respectively be formed of and include semiconductor material. The first source/drain region 314 and the second source/drain region 316 of an individual pillar structure 312 may comprise portions of the semiconductor material doped with one or more conductivity-enhancing species (e.g., at least one P-type dopant, such as one or more of boron, aluminum, and gallium; or at least one N-type dopant, such as one or more of phosphorus, arsenic, antimony, and bismuth). The channel region 318 of an individual pillar structure 312 may comprise an additional portion of the semiconductor material that is substantially undoped with conductivity-enhancing species, or that has one or more of a different type and a different atomic concentration of conductivity-enhancing species than the first source/drain region 314 and the second source/drain region 316. In some embodiments, the channel region 318 of an individual pillar structure 312 is formed of and includes substantially undoped semiconductor material.

The storage node devices 306, at least some of the RDM structures 308, and the VC access devices 310 may, in combination, form the memory cells 324 (e.g., volatile memory cells, such as DRAM cells) of the memory array structure 302. Each memory cell 324 may individually include one of the storage node devices 306, one of the VC access devices 310, and one of the RDM structures 308. For an individual memory cell 324, the storage node device 306 thereof may be coupled to the VC access device 310 thereof by way of the RDM structure 308 thereof.

Still referring to FIG. 2, the WL structures 320 of the memory array structure 302 may at least partially (e.g., substantially) vertically overlap the channel regions 318 of the VC access devices 310, and may horizontally extend in parallel in the X-direction (FIG. 1) completely through the array region 102 and at least partially through the WL exit region 106. At least some of the WL structures 320 may terminate within the WL exit region 106. The WL structures 320 may individually be formed of and include conductive material. In some embodiments, the WL structures 320 are individually formed of and include one or more of W, Ru, Mo, and TiN.

The memory array structure 302 further includes isolation structures 322 vertically overlapping the VC access devices 310. The isolation structures 322 may vertically overlap and be horizontally interposed between horizontally neighboring pillar structures 312. The WL structures 320 may be at least partially embedded within the isolation structures 322. The isolation structures 322 may individually be formed of and include insulative material, such as one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, and TiOₓ), at least one dielectric nitride material (e.g., SiN_{y}), at least one dielectric oxynitride material (e.g., SiOₓN_{y}), at least one dielectric carboxynitride material (e.g., SiOₓC_{z}N_{y}), and amorphous carbon. In some embodiments, the isolation structures 322 are respectively formed of and include SiOₓ (e.g., SiO₂).

The memory array structure 302 further includes DL structures 326 vertically offset from and coupled to the VC access devices 310. For the relative orientation of the memory array structure 302 depicted in FIG. 2, the DL structures 326 vertically overlie the VC access devices 310. However, for a different (e.g., inverted) orientation of the memory array structure 302 (e.g., such as that described below with reference to FIG. 4), the DL structures 326 vertically underlie the VC access devices 310. The DL structures 326 may be coupled to the second source/drain regions 316 of the VC access devices 310. The DL structures 326 may horizontally extend in parallel in the Y-direction (FIG. 1) completely through the array region 102 and at least partially through the DL exit region 104. At least some of the DL structures 326 may terminate within the DL exit region 104. The DL structures 326 may individually be formed of and include conductive material. In some embodiments, the DL structures 326 are individually formed of and include one or more of W, Ru, Mo, and TiN.

Still referring to FIG. 2, DL capping structures 330 may be positioned on or over the DL structures 326. For the relative orientation of the memory array structure 302 depicted in FIG. 2, the DL capping structures 330 vertically overlie the DL structures 326. However, for a different (e.g., inverted) orientation of the memory array structure 302 (e.g., such as that described below with reference to FIG. 4), the DL capping structures 330 vertically underlie the DL structures 326. In addition, DL spacer structures may be formed on or over side surfaces (e.g., sidewalls) of the DL capping structures 330. The DL capping structures 330 and the DL spacer structures may individually be formed of and include at least one insulative material. In some embodiments, the DL capping structures 330 and the DL spacer structures are individually formed of and include one or more of dielectric oxide material (e.g., SiOₓ, such as SiO₂) and dielectric nitride material (e.g., SiN_{y}, such as Si₃N₄).

A shielding structure 332 (e.g., shielding plate) may be positioned on or over the DL capping structures 330. For the relative orientation of the memory array structure 302 depicted in FIG. 2, the shielding structure 332 at least partially vertically overlies the DL capping structures 330. However, for a different (e.g., inverted) orientation of the memory array structure 302 (e.g., such as that described below with reference to FIG. 4), the shielding structure 332 may at least partially vertically underlie the DL capping structures 330. The shielding structure 332 may be configured to shield (e.g., protect) features of the memory array structure 302, such as the DL structures 326, from undesirable electrical interference (e.g., electromagnetic interference (EMI)). As shown in FIG. 2, in some embodiments, the shielding structure 332 includes projections 334 outwardly vertically extending at least partially (e.g., substantially) through vertical spans of the DL capping structures 330 and the DL structures 326. The projections 334 of the shielding structure 332 may be horizontally interposed between horizontally neighboring DL structures 326. In additional embodiments, the shielding structure 332 does not include the projections 334 outwardly vertically extending at least partially through the vertical spans of the DL capping structures 330 and the DL structures 326. The shielding structure 332, including the projections 334 thereof (if any), may be formed of and include conductive material. In some embodiments, the shielding structure 332 is formed of and includes metallic material, such as one or more of at least one metal, at least one alloy, and at least one conductive metal-containing material (e.g., a conductive metal nitride, a conductive metal silicide, a conductive metal carbide, a conductive metal oxide). By way of non-limiting example, the shielding structure 332 may be formed of and include one or more of W, Ru, Mo, and TiN. The shielding structure 332 may be substantially homogeneous, or the shielding structure 332 may be heterogeneous. In some embodiments, the shielding structure 332 is formed of and includes W.

Within the WL exit regions 106, the memory array structure 302 further includes WL contact structures 336 at least partially vertically offset from, and in contact with, the WL structures 320. For the relative orientation of the memory array structure 302 depicted in FIG. 2, the WL contact structures 336 vertically overlie and contact (e.g., physically contact) the WL structures 320. The WL contact structures 336 may respectively vertically extend through vertical spans of the shielding structure 332, the DL capping structures 330, the DL structures 326, and portions of the isolation structures 322, and at least to the WL structures 320. The WL contact structures 336 may be considered to be so-called “edge of array” WL contact structures. The WL contact structures 336 may respectively be formed of and include conductive material. In some embodiments, the WL contact structures 336 are individually formed of and include one or more of W, Ru, Mo, and TiN.

Within the DL exit regions 104, the memory array structure 302 further includes DL contact structures 338 at least partially vertically offset from, and in contact with, the DL structures 326. For the relative orientation of the memory array structure 302 depicted in FIG. 2, the DL contact structures 338 vertically overlie and contact (e.g., physically contact) the DL structures 326. The DL contact structures 338 may respectively vertically extend through vertical spans of the shielding structure 332 and the DL capping structures 330, and at least to the DL structures 326. The DL contact structures 338 may be considered to be so-called “edge of array” DL contact structures. The DL contact structures 338 may respectively be formed of and include conductive material. In some embodiments, the DL contact structures 338 are individually formed of and include one or more of W, Ru, Mo, and TiN.

Still referring to FIG. 2, the memory array structure 302 further includes first routing structures 340 vertically offset from the WL contact structures 336 and the DL contact structures 338. For the relative orientation of the memory array structure 302 depicted in FIG. 2, the first routing structures 340 vertically overlie the WL contact structures 336 and the DL contact structures 338. The first routing structures 340 may, for example, include one or more of first pad structures and first line structures. As shown in FIG. 2, some of the first routing structures 340 may be coupled to the WL contact structures 336, and some others of the first routing structures 340 may be coupled to the DL contact structures 338. In addition, yet still some others of the first routing structures 340 may be coupled to additional contact structures within the memory array structure 302, such as one or more contact structures coupled to the shielding structure 332, for example. The first routing structures 340 may respectively be formed of and include conductive material. In some embodiments, the first routing structures 340 are individually formed of and include one or more of W, Ru, Mo, and TiN.

A third isolation material 342 may be formed on or over portions of at least the first routing structures 340, the WL contact structures 336, the DL contact structures 338, and the shielding structure 332. The third isolation material 342 may also be formed on or over portions of other features of the memory array structure 302 as well. The third isolation material 342 may be formed of and include at least one insulative material. In some embodiments, the third isolation material 342 is formed of and includes dielectric oxide material, such as SiOₓ (e.g., SiO₂). The third isolation material 342 may be substantially homogeneous, or the third isolation material 342 may be heterogeneous. An upper surface of the third isolation material 342 may be formed to be substantially planar. In some embodiments, the upper surface of the third isolation material 342 is formed to be substantially coplanar with upper surfaces of uppermost ones of the first routing structures 340. In additional embodiments, the upper surface of the third isolation material 342 is formed vertically overlie the upper surfaces of the uppermost ones of the first routing structures 340.

Still referring to FIG. 2, the memory array structure 302 may further include second routing structures 346 vertically offset from the memory cells 324. The second routing structures 346 may be vertically interposed between the storage node devices 306 of the memory cells 324 and at least a portion of the second isolation material 304 of the memory array structure 302. For the relative orientation of the memory array structure 302 depicted in FIG. 2, the second routing structures 346 vertically underlie the storage node devices 306 of the memory cells 324. However, for a different (e.g., inverted) orientation of the memory array structure 302 (e.g., such as that described below with reference to FIG. 4), second routing structures 346 may vertically overlie the storage node devices 306 of the memory cells 324. The second routing structures 346 may, for example, include one or more of second pad structures and second line structures. The first routing structures 340 may respectively be formed of and include conductive material. In some embodiments, the first routing structures 340 are individually formed of and include one or more of W, Ru, Mo, and TiN.

Within the DL exit regions 104 and/or the WL exit region 106, the memory array structure 302 may further include first deep contact structures 344 vertically extending from some of the RDM structures 308 to some of the second routing structures 346. The first deep contact structures 344 may couple some of the RDM structures 308 to some of the second routing structures 346. The first deep contact structures 344 may at least partially vertically overlap the storage node devices 306 of the memory cells 324. The first deep contact structures 344 may respectively be formed of and include conductive material. In some embodiments, the first deep contact structures 344 are individually formed of and include one or more of W, Ru, Mo, and TiN.

In additional embodiments, the second routing structures 346 and/or the first deep contact structures 344 are omitted (e.g., absent) from the memory array structure 302. For example, the memory array structure 302 may be free of second routing structures 346 vertically interposed between the storage node devices 306 and the front side F₃₀₂ of the memory array structure 302, and may also be free of first deep contact structures 344 vertically extending from some of the RDM structures 308 to some of any such omitted second routing structures 346.

Still referring to FIG. 2, the additional memory array structure 402 may vertically overlie and be bonded (e.g., dielectric-to-dielectric bonded, metal-to-metal bonded) to the memory array structure 302. The additional memory array structure 402 includes features (e.g., regions, sections, structures, circuitry, devices) functionally similar to respective features of the memory array structure 302. In FIG. 2, and subsequent figures, such features of the additional memory array structure 402 will be understood to be “additional” features, and are referred to with reference numerals similar to those for respective features of the memory array structure 302, but incremented by 100. To avoid repetition, not all features of the additional memory array structure 402 shown in FIG. 2 (and subsequent figures) are described in detail herein. Rather, unless described otherwise below, an “additional” feature of the additional memory array structure 402 designated by a reference numeral that is a 100 increment of the reference numeral of a previously described feature the memory array structure 302 will be understood to be substantially similar to and have substantially the same functions as the previously described feature. As a non-limiting example, additional memory cells 434 (including additional storage node devices 406 and additional VC access devices thereof, without limitation) of the additional memory array structure 402 may be substantially similar to the memory cells 324 (including the storage node devices 306 and the VC access devices thereof, without limitation) of the memory array structure 302 previously described herein. As an additional non-limiting example, additional WL structures 420 of the additional memory array structure 402 may be substantially similar to the WL structures 320 previously described herein. As a further non-limiting example, additional DL structures 426 of the additional memory array structure 402 may be substantially similar to the DL structures 326 of the memory array structure 302 previously described herein. As yet still a further non-limiting example, an additional shielding structure 432 of the additional memory array structure 402 may be substantially similar to the shielding structure 332 of the memory array structure 302 previously described herein.

The front side F₄₀₂ of the additional memory array structure 402 may be considered a side (e.g., end surface) most vertically proximate to vertical ends of the additional storage node device 406 that are most vertically distal from the additional VC access devices 410. In addition, the back side B₄₀₂ of the additional memory array structure 402 may be considered an additional side (e.g., additional end surface) most vertically proximate to vertical ends of the additional VC access devices 410 that are most vertically distal from the additional storage node device 406. In some embodiments, the front side F₄₀₂ of the additional memory array structure 402 is positioned relatively vertically closer to the additional storage node devices 406 of the additional memory cells 424 than is the back side B₄₀₂ of the additional memory array structure 402; and the back side B₄₀₂ of the additional memory array structure 402 is positioned relatively vertically closer to the additional VC access devices 410 of the additional memory cells 424 than is the front side F₄₀₂ of the additional memory array structure 402. As shown in FIG. 2, the additional storage node devices 406 of the additional memory cells 424 may be vertically interposed between the front side F₄₀₂ of the additional memory array structure 402 and the additional VC access devices 410 of the additional memory cells 424; and the additional VC access devices 410 of the additional memory cells 424 may be vertically interposed between the back side B₄₀₂ of the additional memory array structure 402 and the additional storage node devices 406 of the additional memory cells 424.

In the configuration shown in FIG. 2, the microelectronic device 100A (and, hence, the microelectronic device 100 (FIG. 1)) may have a so-called “back-to-back” (B2B) arrangement of the additional memory array structure 402 relative to the memory array structure 302. In the B2B arrangement of the additional memory array structure 402 relative to the memory array structure 302, the back side B₄₀₂ of the additional memory array structure 402 may be bonded to the back side B₃₀₂ of the memory array structure 302 at an interface. Accordingly, an orientation of the additional memory array structure 402 is vertically inverted relative to an orientation of the memory array structure 302.

The back side B₄₀₂ of the additional memory array structure 402 may be bonded to the back side B₃₀₂ of the memory array structure 302 through a combination of dielectric-to-dielectric bonding and metal-to-metal bonding. For example, the additional third isolation material 442 and at least some of the additional first routing structures 440 of the additional memory array structure 402 may be provided in physical contact with the third isolation material 342 and at least some of the first routing structures 340 of the memory array structure 302, respectively; and then the additional third isolation material 442, the third isolation material 342, the additional first routing structures 440, and the first routing structures 340 may be exposed to annealing conditions to form bonds (e.g., dielectric-to-dielectric bonds, such as oxide-to-oxide bonds) between the additional third isolation material 442 and the third isolation material 342, and additional bonds (e.g., metal-to-metal bonds) between the additional first routing structures 440 and the additional first routing structures 440. By way of non-limiting example, the additional third isolation material 442, the third isolation material 342, the additional first routing structures 440, and the first routing structures 340 may be exposed to a temperature greater than or equal to about 400° C. (e.g., within a range of from about 400° C. to about 800° C., greater than about 800° C.) to form bonds between the additional third isolation material 442 and the third isolation material 342 and bonds between the additional first routing structures 440 and the first routing structures 340. Bonding the additional first routing structures 440 to the first routing structures 340 may form bonded routing structures individually including a lower portion including an individual first routing structure 340, and an upper portion integral and continuous within the lower portion and including an individual additional first routing structure 440. While FIG. 2 includes a dashed line representing an initial interface location between the additional memory array structure 402 and the memory array structure 302 before the bonding process, the additional third isolation material 442 and the third isolation material 342 may be integral and continuous with one another following the bonding process, and the portions (e.g., upper portion formed from an additional first routing structure 440, lower portion formed from a first routing structure 340) of individual bonded routing structures may also be integral and continuous with one another following the bonding process. The additional memory array structure 402 may be attached to the memory array structure 302 without a bond line or with a bond line.

As shown in FIG. 2, the additional memory array structure 402 includes features (e.g., regions, sections, structures, circuitry, devices) having modifications (e.g., changes to geometric configuration and/or position) relative to corresponding features of the memory array structure 302, as well as further features not having counterparts within the memory array structure 302. Such relatively modified features and further features of the additional memory array structure 402 may at least partially be associated with the position and orientation of the additional memory array structure 402 within the microelectronic device 100A, and are described in further detail below.

Within the WL exit regions 106, the additional WL contact structures 436 of the additional memory array structure 402 may be horizontally offset from positions of the WL contact structures 336 of the memory array structure 302, and may have different geometric configurations and relative vertical positions within the additional memory array structure 402 relative to the WL contact structures 336 of the memory array structure 302. As shown in FIG. 2, at least some of the additional WL contact structures 436 may be horizontally positioned relatively closer to the additional memory cells 424 of the additional memory array structure 402 as compared to horizontal positions of at least some of the WL contact structures 336 relative to the memory cells 324 of the memory array structure 302. In addition, the additional WL contact structures 436 may vertically extend from some of the additional RDM structures 408 to the additional WL structures 420. The additional WL contact structures 436 may couple the some of the additional RDM structures 408 to the additional WL structures 420. The additional WL contact structures 436 may individually vertically overlap portions of the additional VC access devices 410, such as the additional first source/drain region 414 of respective ones of the additional VC access devices 410. The additional WL contact structures 436 may respectively be formed of and include conductive material. In some embodiments, the additional WL contact structures 436 are individually formed of and include one or more of W, Ru, Mo, and TiN.

Within the DL exit regions 104, the additional DL contact structures 438 of the additional memory array structure 402 may be horizontally offset from positions of the DL contact structures 338 of the memory array structure 302, and may have different geometric configurations and relative vertical positions within the additional memory array structure 402 relative to the WL contact structures 336 of the memory array structure 302. As shown in FIG. 2, at least some of the additional DL contact structures 338 may be horizontally positioned relatively closer to the additional memory cells 424 of the additional memory array structure 402 as compared to horizontal positions of at least some of the DL contact structures 338 relative to the memory cells 324 of the memory array structure 302. In addition, the additional DL contact structures 438 may vertically extend from some others of the additional RDM structures 408 to the additional DL structures 426. The additional DL contact structures 438 may couple the some others of the additional RDM structures 408 to the additional DL structures 426. The additional DL contact structures 438 may individually vertically overlap portions of the additional VC access devices 410, such as each of the additional first source/drain region 414, the additional channel region 418, and the additional second source/drain region 416 of respective ones of the additional VC access devices 410. The additional DL contact structures 438 may respectively be formed of and include conductive material. In some embodiments, the additional DL contact structures 438 are individually formed of and include one or more of W, Ru, Mo, and TiN.

Within the DL exit regions 104 and/or the WL exit region 106, the additional memory array structure 402 may include a relatively greater quantity of the additional first deep contact structures 444 and when compared to a quantity of the first deep contact structures 344 within the memory array structure 302. Some of the additional first deep contact structures 444, in combination with additional features (e.g., the additional WL contact structures 436, some of the additional RDM structures 408, some of the additional second routing structures 446, some of additional contact structures, some of additional routing structures) of the additional memory array structure 402, facilitate signal routing paths extending to the additional WL structures 420 of the additional memory array structure 402. Some others of the additional first deep contact structures 444, in combination with additional features (e.g., the additional DL contact structures 438, some others of the additional RDM structures 408, some others of the additional second routing structures 446, some others of additional contact structures, some others of additional routing structures) of the additional memory array structure 402, facilitate signal routing paths extending to the additional DL structures 426 of the additional memory array structure 402. Still others of the additional first deep contact structures 444, in combination with additional features of the additional memory array structure 402, respectively facilitate other signal routing paths extending within the additional memory array structure 402 (e.g., to the additional shielding structure 432) or through the additional memory array structure 402 (e.g., to the memory array structure 302).

Within the DL exit regions 104 and/or the WL exit region 106, the additional memory array structure 402 may further include second deep contact structures 435 vertically extending from yet some others of the additional RDM structures 408 to some of the additional first routing structures 440. The second deep contact structures 435 may couple the yet some others of the additional RDM structures 408 to the some of the additional first routing structures 440. The second deep contact structures 435 may at least partially vertically overlap the additional VC access devices 410, the additional WL structures 420, the additional DL structures 426, the additional DL capping structures 430, and the additional shielding structure 432 of the additional memory array structure 402. The first deep contact structures 344 may, in combination with additional features (e.g., some of the additional first routing structures 440, some of the additional RDM structures 408, some of the additional first deep contact structures 444, some of the additional second routing structures 446, some of additional contact structures, additional routing structures) of the additional memory array structure 402, facilitate signal routing paths extending through the additional memory array structure 402 and into the memory array structure 302. The second deep contact structures 435 may respectively be formed of and include conductive material. In some embodiments, the second deep contact structures 435 are individually formed of and include one or more of W, Ru, Mo, and TiN.

Still referring to FIG. 2, the additional memory array structure 402 may further include third routing structures 448 vertically offset from the additional second routing structures 446. The third routing structures 448 may be vertically interposed between the additional second routing structures 446 and at least a portion of the additional second isolation material 404. In some embodiments, a portion of the additional second isolation material 404 is vertically interposed between the third routing structures 448 and the front side F₄₀₂ of the additional memory array structure 402. For the relative orientation of the additional memory array structure 402 depicted in FIG. 2, the third routing structures 448 vertically overlie the additional second routing structures 446. The third routing structures 448 may, for example, include one or more of third pad structures and third line structures. The third routing structures 448 may respectively be formed of and include conductive material. In some embodiments, the third routing structures 448 are individually formed of and include one or more of W, Ru, Mo, and TiN.

The additional memory array structure 402 may further include interconnect structures 450 vertically extending from some of the third routing structures 448 to some of the additional second routing structures 446. The interconnect structures 450 may couple the some of the third routing structures 448 to the some of the additional second routing structures 446. The interconnect structures 450 may respectively be formed of and include conductive material. In some embodiments, the interconnect structures 450 are individually formed of and include one or more of W, Ru, Mo, and TiN.

In additional embodiments, the third routing structures 448 and the interconnect structures 450 are omitted (e.g., absent) from the additional memory array structure 402. Namely, similar to the memory array structure 302, the additional memory array structure 402 may be free of third routing structures 448 and interconnect structures 450 vertically interposed between the additional second routing structures 446 and the front side F₄₀₂ of the additional memory array structure 402.

Still referring to FIG. 2, the control circuitry structure 502 may vertically overlie and be bonded (e.g., dielectric-to-dielectric bonded) to the additional memory array structure 402. The control circuitry structure 502 may include, without limitation, control logic circuitry for the microelectronic device 100A. The control logic circuitry may, for example, be configurated and employed to control at least some operations (e.g., read operations, write operations), on the memory cells 324 of the memory array structure 302 and the additional memory cells 424 of the additional memory array structure 402 during use and operation of the microelectronic device 100A. At least some of the control logic circuitry (e.g., sense amplifier (SA) circuitry, sub-word line drive (SWD) circuitry) may be positioned within a horizontal area of the array region 102 of the microelectronic device 100A (and, hence, the microelectronic device 100). As described in further detail below, the control logic circuitry of the control circuitry structure 502 includes transistors 510 and fourth routing structures 530 vertically offset from and coupled to the transistors 510. Different arrangements and interactions of the transistors 510 and the fourth routing structures 530 form different control logic devices 526 of the microelectronic device 100A. The control circuitry structure 502 also includes additional features (e.g., materials, structures, regions, circuitry, devices), as described in further detail below.

The back side B₅₀₂ of the control circuitry structure 502 may be considered a side (e.g., end surface) relatively more vertically proximate to the transistors 510 of the control logic devices 526 than to the fourth routing structures 530 of the control logic devices 526. Relative to an individual transistor 510, the back side B₅₀₂ of the control circuitry structure 502 may be relatively vertically closer to a channel region 516 of the transistor 510 than to a gate structure 518 (e.g., a gate electrode) of the transistor 510. In addition, a front side F₅₀₂ of the control circuitry structure 502 may be considered an additional side (e.g., additional end surface) relatively more vertically proximate to the fourth routing structures 530 of the control logic devices 526 than to the transistors 510 of the control logic devices 526. Relative to an individual transistor 510, the front side F₅₀₂ of the control circuitry structure 502 may be relatively vertically closer to the gate structure 518 of the transistor 510 than to the channel region 516 of the transistor 510. As shown in FIG. 2, the transistors 510 of the control logic devices 526 may be vertically interposed between the front side F₅₀₂ of the control circuitry structure 502 and the fourth routing structures 530 of the control logic devices 526; and the fourth routing structures 530 of the control logic devices 526 may be vertically interposed between the front side F₅₀₂ of the control circuitry structure 502 and the transistors 510 of the control logic devices 526. As described in further detail below, additional features of the control circuitry structure 502 may be vertically interposed between the back side B₅₀₂ of the control circuitry structure 502 and the transistors 510 of the control logic devices 526; and further features of the control circuitry structure 502 may be vertically interposed between the front side F₅₀₂ of the control circuitry structure 502 and the fourth routing structures 530 of the control logic devices 526.

In the configuration shown in FIG. 2, the microelectronic device 100A (and, hence, the microelectronic device 100 (FIG. 1)) may have a so-called “back-to-front” (B2F) arrangement of the control circuitry structure 502 relative to the additional memory array structure 402. In the B2F arrangement of the control circuitry structure 502 relative to the additional memory array structure 402, the back side B₅₀₂ of the control circuitry structure 502 may be bonded to the front side F₄₀₂ of the additional memory array structure 402 at an interface.

For the configuration of the microelectronic device 100A shown in FIG. 2, wherein the back side B₅₀₂ of the control circuitry structure 502 is attached to the front side F₄₀₂ of the additional memory array structure 402, a fourth isolation material 504 of the control circuitry structure 502 may be bonded (e.g., dielectric-to-dielectric bonded) to the additional second isolation material 404 of the control circuitry structure 502. The fourth isolation material 504 may be formed of and include at least one insulative material. A material composition of the fourth isolation material 504 may be substantially the same as a material composition of the additional second isolation material 404; or the material composition of the fourth isolation material 504 may be different than the material composition of the additional second isolation material 404. In some embodiments, the fourth isolation material 504 is formed of and includes dielectric oxide material, such as SiOₓ (e.g., SiO₂). The fourth isolation material 504 may be substantially homogeneous, or the fourth isolation material 504 may be heterogeneous.

To bond the back side B₅₀₂ of the control circuitry structure 502 to the front side F₄₀₂ of the additional memory array structure 402, the fourth isolation material 504 of the control circuitry structure 502 may be provided in physical contact with the additional second isolation material 404 of the additional memory array structure 402 at an interface, and then the fourth isolation material 504 and the additional second isolation material 404 may be exposed to annealing conditions to form bonds (e.g., dielectric-to-dielectric bonds, such as oxide-to-oxide bonds) between the fourth isolation material 504 and the additional second isolation material 404. By way of non-limiting example, the fourth isolation material 504 and the additional second isolation material 404 may be exposed to a temperature greater than or equal to about 400° C. (e.g., within a range of from about 400° C. to about 800° C., greater than about 800° C.) to form dielectric-to-dielectric bonds between the fourth isolation material 504 and the additional second isolation material 404. In some embodiments, the fourth isolation material 504 and the additional second isolation material 404 are exposed to at least one temperature greater than about 800° C. to form oxide-to-oxide bonds between the fourth isolation material 504 and the additional second isolation material 404. In FIG. 2, the fourth isolation material 504 and the additional second isolation material 404 are distinguished from one another by way of a dashed line representing the interface therebetween prior to bonding. However, the fourth isolation material 504 and the additional second isolation material 404 may be integral and continuous with one another following the bonding process. The control circuitry structure 502 may be attached to the additional memory array structure 402 without a bond line or with a bond line.

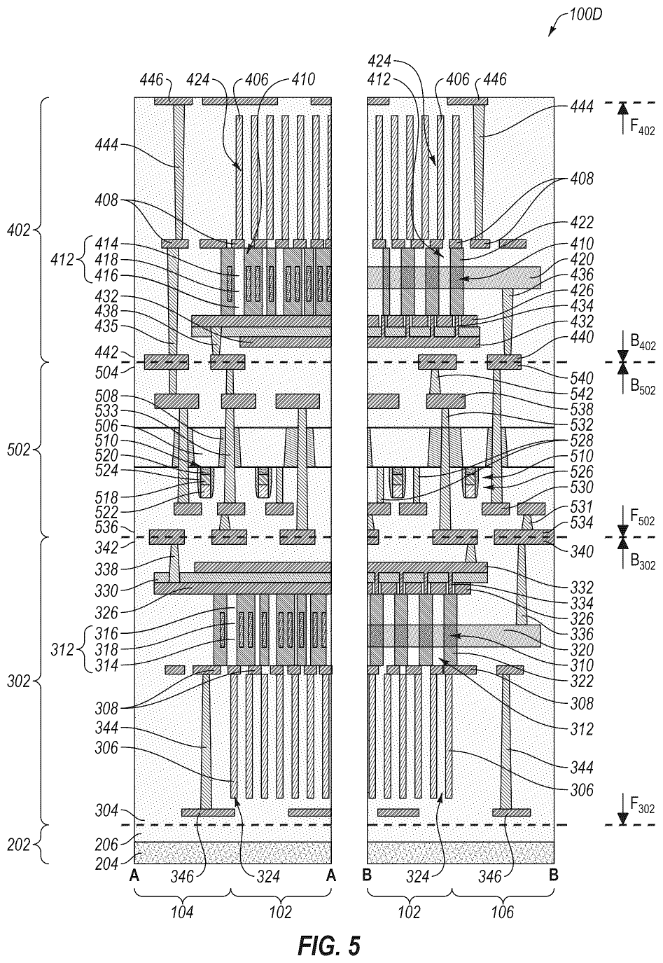

Still referring to FIG. 2, the control circuitry structure 502 may formed to further include a second base structure 506 and further isolation structures 508 (e.g., additional STI structures) vertically extending at least partially (e.g., completely) through the second base structure 506. The second base structure 506 and further isolation structures 508 may respectively be at least partially vertically offset from the fourth isolation material 504. For example, for the relative orientation of the control circuitry structure 502 (e.g., relative to the additional memory array structure 402) shown in FIG. 2, the second base structure 506 and further isolation structures 508 may at least partially vertically overlie the fourth isolation material 504. However, for a different (e.g., inverted) orientation of the control circuitry structure 502 (e.g., such as that described below with reference to FIG. 5), the second base structure 506 and further isolation structures 508 may at least partially vertically underlie the fourth isolation material 504.

The second base structure 506 of the control circuitry structure 502 includes a base material or construction upon and/or within which additional features (e.g., materials, structures, circuitry, devices) are formed. The second base structure 506 comprise semiconductor structure or base semiconductor material on a supporting structure. For example, the second base structure 506 may comprise a silicon substrate, or another bulk substrate comprising semiconductor material. In some embodiments, the second base structure 506 comprises a semiconductor base structure (e.g., a silicon base structure, such as a polycrystalline silicon base structure or a monocrystalline silicon base structure).

The further isolation structures 508 may comprise trenches (e.g., openings, vias, apertures) formed within the semiconductor material of the second base structure 506 filled with insulative material, such as one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, and TiOₓ), at least one dielectric nitride material (e.g., SiN_{y}), at least one dielectric oxynitride material (e.g., SiOₓN_{y}), at least one dielectric carboxynitride material (e.g., SiOₓC_{z}N_{y}), and amorphous carbon. In some embodiments, the further isolation structures 508 are respectively formed of and include SiOₓ (e.g., SiO₂).

The further isolation structures 508 may, for example, be employed as STI structures within the second base structure 506. The further isolation structures 508 may be formed to vertically extend through the second base structure 506. Each of the further isolation structures 508 may be formed to exhibit substantially the same dimensions and shape as each other of the further isolation structures 508, or at least one of the further isolation structures 508 may be formed to exhibit one or more of different dimensions and a different shape than at least one other of the further isolation structures 508. As a non-limiting example, each of the further isolation structures 508 may be formed to exhibit substantially the same vertical dimension(s) and substantially the same vertical cross-sectional shape(s) as each other of the further isolation structures 508; or at least one of the further isolation structures 508 may be formed to exhibit one or more of different vertical dimension(s) and different vertical cross-sectional shape(s) than at least one other of the further isolation structures 508. In some embodiments, the further isolation structures 508 are all formed to vertically extend completely through the semiconductor material of the second base structure 506. As another non-limiting example, each of the further isolation structures 508 may be formed to exhibit substantially the same horizontal dimension(s) and substantially the same horizontal cross-sectional shape(s) as each other of the further isolation structures 508; or at least one of the further isolation structures 508 may be formed to exhibit one or more of different horizontal dimension(s) (e.g., relatively larger horizontal dimension(s), relatively smaller horizontal dimension(s)) and different horizontal cross-sectional shape(s) than at least one other of the further isolation structures 508. In some embodiments, at least one of the further isolation structures 508 is formed to have one or more different horizontal dimensions than at least one other of the further isolation structures 508.

Still referring to FIG. 2, the transistors 510 of the control circuitry structure 502 may individually include a first conductively doped region 512 (e.g., a first source/drain region), a second conductively doped region 514 (e.g., a second source/drain region), the channel region 516, a gate structure 518 (e.g., a gate electrode), and a gate dielectric material 520. For an individual transistor 510, the first conductively doped region 512 and the second conductively doped region 514 thereof may be formed within the semiconductor material of the second base structure 506; the channel region 516 thereof may be formed within the semiconductor material of the second base structure 506 and may be horizontally interposed between the first conductively doped region 512 and the second conductively doped region 514 thereof; the gate structure 518 thereof may be vertically offset from and may horizontally overlap the channel region 516 thereof; and the gate dielectric material 520 (e.g., dielectric oxide material) may be vertically interposed between the gate structure 518 and the channel region 516. As shown in FIG. 2, the control circuitry structure 502 may also include insulative capping structures 522 on surfaces of the gate structures 518 opposite those associated with the gate dielectric material 520, as well as insulative spacer structures 524 in physical contact with side surfaces (e.g., sidewalls) of the gate structures 518.

For an individual transistor 510, the first conductively doped region 512 and the second conductively doped region 514 thereof may respectively comprise semiconductor material of the second base structure 506 doped with one or more desired conductivity-enhancing dopants. In some embodiments, the first conductively doped region 512 and the second conductively doped region 514 of the transistor 510 respectively comprise the semiconductor material doped with at least one N-type dopant (e.g., one or more of phosphorus, arsenic, antimony, and bismuth). In some of such embodiments, the channel region 516 of the transistor 510 comprises the semiconductor material doped with at least one P-type dopant (e.g., one or more of boron, aluminum, and gallium). In some other of such embodiments, the channel region 516 of the transistor 510 comprises substantially undoped semiconductor material. In additional embodiments, for an individual transistor 510, the first conductively doped region 512 and the second conductively doped region 514 thereof respectively comprise the semiconductor material doped with at least one P-type dopant (e.g., one or more of boron, aluminum, and gallium). In some of such additional embodiments, the channel region 516 of the transistor 510 comprises the semiconductor material doped with at least one N-type dopant (e.g., one or more of phosphorus, arsenic, antimony, and bismuth). In some other of such additional embodiments, the channel region 516 of the transistor 510 comprises substantially undoped semiconductor material.

The gate structures 518 (e.g., gate electrodes, gates) may individually horizontally extend between and be employed by multiple transistors 510. The gate structures 518 may be formed of and include conductive material. The gate structures 518 may individually be substantially homogeneous, or the gate structures 518 may individually be heterogeneous. In some embodiments, the gate structures 518 are each substantially homogeneous. In additional embodiments, the gate structures 518 are each heterogeneous. Individual gate structures 518 may, for example, be formed of and include a stack of at least two different conductive materials.

Still referring to FIG. 2, the control circuitry structure 502 further includes first contact structures 528 (e.g., source/drain contact structures) individually vertically offset from and in contact (e.g., physical contact, electrical contact) with one of the first conductively doped region 512 and the second conductively doped region 514 of respective ones of the transistors 510. For example, for the relative orientation of the control circuitry structure 502 shown in FIG. 2, the first contact structures 528 may at least partially vertically overlie the first conductively doped region 512 and the second conductively doped region 514. However, for a different (e.g., inverted) orientation of the control circuitry structure 502 (e.g., such as that described below with reference to FIG. 5), the first contact structures 528 may at least partially vertically underlie the first conductively doped region 512 and the second conductively doped region 514. In some embodiments, the first contact structures 528 individually vertically overlie, horizontally overlap, and physically contact one of the first conductively doped region 512 and the second conductively doped region 514 of respective ones of the transistors 510. The first contact structures 528 may individually be formed of and include conductive material. In some embodiments, the first contact structures 528 are individually formed of and include one or more of W, Ru, Mo, and TiN.

As previously described herein, the fourth routing structures 530 of the control circuitry structure 502 are vertically offset from the transistors 510 of the control circuitry structure 502. For example, for the relative orientation of the control circuitry structure 502 shown in FIG. 2, the fourth routing structures 530 may vertically overlie the transistors 510. However, for a different (e.g., inverted) orientation of the control circuitry structure 502 (e.g., such as that described below with reference to FIG. 5), the fourth routing structures 530 may vertically underlie the transistors 510. As shown in FIG. 2, some of the fourth routing structures 530 may be coupled to the first contact structures 528 (and, hence, the transistors 510). The fourth routing structures 530 may respectively be formed of and include conductive material. In some embodiments, the fourth routing structures 530 are individually formed of and include one or more of W, Ru, Mo, and TiN.

The transistors 510, the first contact structures 528, and at least some of the fourth routing structures 530 may form control logic circuitry of various control logic devices 526 configured to control various operations of various features (e.g., the memory cells 324, the additional memory cells 424) of the microelectronic device 100A (and, hence, the microelectronic device 100 (FIG. 1)). In some embodiments, the control logic devices 526 comprise complementary metal-oxide-semiconductor (CMOS) circuitry. As a non-limiting example, the control logic devices 526 may include one or more (e.g., each) of charge pumps (e.g., V_{CCP} charge pumps, V_{NEGWL} charge pumps, DVC2 charge pumps), delay-locked loop (DLL) circuitry (e.g., ring oscillators), V_{dd} regulators, drivers (e.g., main WL drivers (MWD), SWD), page buffers, decoders (e.g., local deck decoders, column decoders, row decoders), sense amplifiers (e.g., equalization (EQ) amplifiers, isolation (ISO) amplifiers, NMOS sense amplifiers (NSAs), PMOS sense amplifiers (PSAs)), repair circuitry (e.g., column repair circuitry, row repair circuitry), I/O devices (e.g., local I/O devices), memory test devices, array multiplexers (MUX), error checking and correction (ECC) devices, self-refresh/wear leveling devices, and other chip/deck control circuitry. Different regions (e.g., the array region 102, the DL exit region 104, the WL exit region 106) of the control circuitry structure 502 may have different control logic devices 526 formed within horizontal areas thereof.

The control circuitry structure 502 may further include fifth routing structures 534 and second contact structures 531 vertically offset from the control logic devices 526. For example, for the relative orientation of the control circuitry structure 502 shown in FIG. 2, the fifth routing structures 534 and second contact structures 531 may vertically overlie the control logic devices 526. However, for a different (e.g., inverted) orientation of the control circuitry structure 502 (e.g., such as that described below with reference to FIG. 5), the fifth routing structures 534 and second contact structures 531 may vertically underlie the control logic devices 526. The fifth routing structures 534 may be formed to horizontally extend in desirable paths relative to the control logic devices 526. As shown in FIG. 2, some of the fifth routing structures 534 may be coupled to some of the fourth routing structures 530 (and, hence, at least some of the control logic devices 526) by way of the second contact structures 531. The second contact structures 531 may vertically extend from the some of the fifth routing structures 534 to the some of the fourth routing structures 530. The fifth routing structures 534 and the second contact structures 531 may respectively be formed of and include conductive material. In some embodiments, the fifth routing structures 534 and the second contact structures 531 are individually formed of and include one or more of W, Ru, Mo, and TiN.

Still referring to FIG. 2, third contact structures 532 may be formed to vertically extend from some of the fifth routing structures 534 of the control circuitry structure 502 to some of the third routing structures 448 of the additional memory array structure 402. In additional embodiments wherein the additional memory array structure 402 is free of the third routing structures 448 (and the interconnect structures 450), the third contact structures 532 may vertically extend to the additional second routing structures 446 of the additional memory array structure 402. One or more (e.g., each) of the third contact structures 532 may be formed to horizontally overlap and vertically extend through one or more of the further isolation structures 508 (e.g., STI structures) of the control circuitry structure 502. Optionally, one or more other of the third contact structures 532 may be formed to horizontally overlap and vertically extend through the semiconductor material of second base structure 506 of the control circuitry structure 502. The third contact structures 532 may facilitate (in combination with at least the second contact structures 531, the fifth routing structures 534, the third routing structures 448 (if any), the interconnect structures 450 (if any), the additional second routing structures 446, the additional first deep contact structures 444, the additional RDM structures 408, the additional WL contact structures 436, the additional WL structures 420, the additional DL contact structures 438, the additional DL structures 426, the second deep contact structures 435, the additional first routing structures 440, the first routing structures 340, the WL contact structures 336, the WL structures 320, the DL contact structures 338, and the DL structures 326) operable communication between the control logic devices 526 and each of the additional memory cells 424 of the additional memory array structure 402 and the memory cells 324 of the memory array structure 302. The third contact structures 532 may respectively be formed of and include conductive material. In some embodiments, the third contact structures 532 are individually formed of and include one or more of W, Ru, Mo, and TiN.

The third contact structures 532 may be formed after bonding the control circuitry structure 502 to the additional memory array structure 402. In some embodiments, one or more features of the control circuitry structure 502 operatively associated with the third contact structures 532 are also formed after bonding the control circuitry structure 502 to the additional memory array structure 402. For example, one or more of the second contact structures 531 and the fifth routing structures 534 may be formed after bonding the control circuitry structure 502. In some embodiments, the fifth routing structures 534 are formed after forming the third contact structures 532 and the second contact structures 531, and the second contact structures 531 are formed before, during, or after the formation of the third contact structures 532.

A fifth isolation material 536 may be formed on or over portions of at least the second base structure 506, the transistors 510, the first contact structures 528, the fourth routing structures 530, the control logic devices 526, the second contact structures 531, the fifth routing structures 534, and the third contact structures 532. In some embodiments, the fifth isolation material 536 is formed of and includes dielectric oxide material, such as SiOₓ (e.g., SiO₂). The fifth isolation material 536 may be substantially homogeneous, or the fifth isolation material 536 may be heterogeneous. An upper surface of the fifth isolation material 536 may be formed to be substantially planar. In some embodiments, the upper surface of the fifth isolation material 536 is formed be substantially coplanar with upper surfaces of the fifth routing structures 534. In additional embodiments, the upper surface of the fifth isolation material 536 is formed to be vertically offset from (e.g., to vertically overlie) the upper surfaces of the fifth routing structures 534.

The microelectronic device 100A (and, hence, the microelectronic device 100 (FIG. 1)) may be formed to further include back-end-of-line (BEOL) structures vertically offset from (e.g., vertically overlying) the fifth routing structures 534 of the control circuitry structure 502. For example, at least one additional routing tier (e.g., at least two additional routing tiers) including additional conductive routing structures may be formed over the fifth routing structures 534; and conductive pad structures may be formed over the additional routing structures. In addition, additional contact structures may be formed to couple different additional conductive routing structures with one another, different fifth routing structures 534, and different conductive pad structures, as desired. The BEOL structures may be formed of and include conductive material. In some embodiments, the BEOL structures are individually formed of and include one or more of W, Cu, Al, Ru, Mo, and TiN.

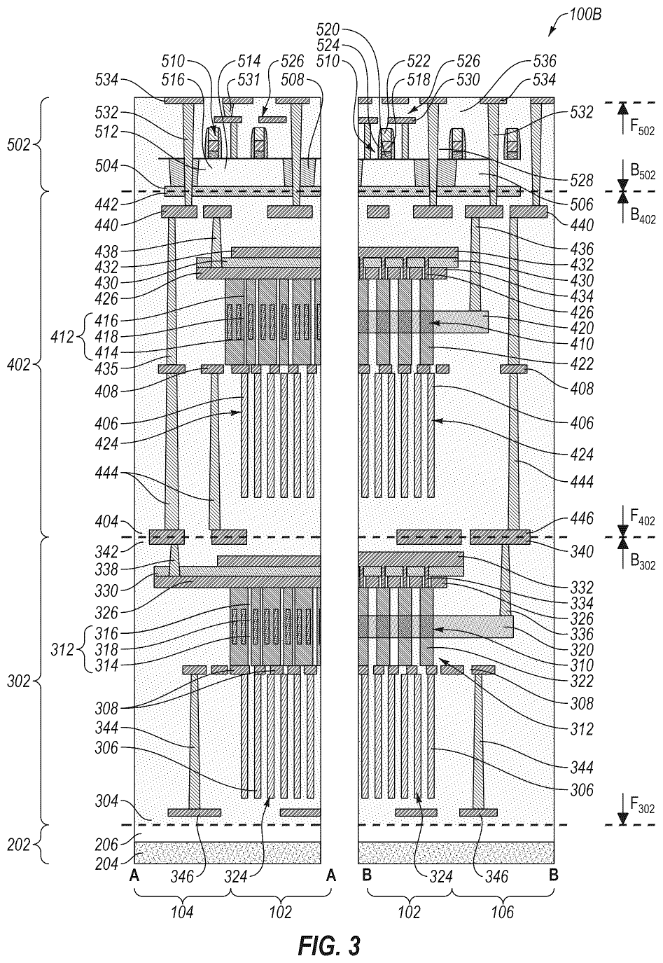

As shown in FIG. 2, the microelectronic device 100A (and, hence, the microelectronic device 100 (FIG. 1)) includes the additional memory array structure 402 vertically overlying and bonded to the memory array structure 302 in a B2B arrangement, and the control circuitry structure 502 vertically overlying and bonded to the additional memory array structure 402 in a B2F arrangement. In additional embodiments, one or more of the memory array structure 302, the additional memory array structure 402, and the control circuitry structure 502 is oriented and/or arranged differently than as previously described herein with reference to FIG. 2. Some such embodiments are described in further detail below with reference to FIGS. 3 through 5. To avoid repetition, not all features shown in FIGS. 3 through 5 are described in detail herein. Rather, unless described otherwise below, a feature shown in any one FIGS. 3 through 5 designated by a reference numeral that is the same as that for a feature previously described with reference to one or more of FIGS. 1 and 2 will be understood to be substantially similar to and have substantially the same functions as the previously described feature.

Referring to FIG. 3, the microelectronic device 100B (and, hence, the microelectronic device 100 (FIG. 1)) may include the carrier structure 202, the memory array structure 302, the additional memory array structure 402, and the control circuitry structure 502 previously described herein with reference to FIG. 2. However, an orientation of the additional memory array structure 402 is vertically inverted relative to that previously described herein with reference to FIG. 2, while maintaining the orientations of the memory array structure 302 and the control circuitry structure 502 previously described herein with reference to FIG. 2. As a result, the microelectronic device 100B includes the additional memory array structure 402 vertically overlying and bonded to the memory array structure 302 in a F2B arrangement, and the control circuitry structure 502 vertically overlying and bonded to the additional memory array structure 402 in a B2B arrangement. Namely, as shown in FIG. 3, the front side F₄₀₂ of the additional memory array structure 402 is bonded to the back side B₃₀₂ of the memory array structure 302, and the back side B₅₀₂ of the control circuitry structure 502 is bonded to the back side B₄₀₂ of the additional memory array structure 402. Thus, for the configuration of the microelectronic device 100B, vertical orientations and vertical positions of features of the additional memory array structure 402 may be vertically inverted relative to vertical orientations and vertical positions of corresponding features of the additional memory array structure 402 within the configuration of the microelectronic device 100A previously described with reference to FIG. 2. Consequently, as described in further detail below, configurations of some of the features of the additional memory array structure 402 and/or interactions between some of the features of the additional memory array structure 402 and some other features of the microelectronic device 100B may be modified relative to those of corresponding features within the microelectronic device 100A (FIG. 2).

For the F2B arrangement of the additional memory array structure 402 and the memory array structure 302 of the microelectronic device 100B, the front side F₄₀₂ of the additional memory array structure 402 may be bonded to the back side B₃₀₂ of the memory array structure 302 through a combination of dielectric-to-dielectric bonding and metal-to-metal bonding. For example, the additional second isolation material 404 and at least some of the additional second routing structures 446 of the additional memory array structure 402 may be provided in physical contact with the third isolation material 342 and at least some of the first routing structures 340 of the memory array structure 302, respectively; and then the additional second isolation material 404, the third isolation material 342, the additional second routing structures 446, and the first routing structures 340 may be exposed to annealing conditions to form bonds (e.g., dielectric-to-dielectric bonds, such as oxide-to-oxide bonds) between the additional second isolation material 404 and the third isolation material 342, and additional bonds (e.g., metal-to-metal bonds) between the additional second routing structures 446 and the additional first routing structures 440. By way of non-limiting example, the additional second isolation material 404, the third isolation material 342, the additional second routing structures 446, and the first routing structures 340 may be exposed to a temperature greater than or equal to about 400° C. (e.g., within a range of from about 400° C. to about 800° C., greater than about 800° C.) to form bonds between the additional second isolation material 404 and the third isolation material 342 and bonds between the additional second routing structures 446 and the first routing structures 340. Bonding the additional second routing structures 446 to the first routing structures 340 may form bonded routing structures individually including a lower portion including an individual first routing structure 340, and an upper portion integral and continuous within the lower portion and including an individual additional second routing structure 446. While FIG. 3 includes a dashed line representing an initial interface location between the additional memory array structure 402 and the memory array structure 302 before the bonding process, the additional second isolation material 404 and the third isolation material 342 may be integral and continuous with one another following the bonding process, and the portions (e.g., upper portion formed from an additional second routing structure 446, lower portion formed from a first routing structure 340) of individual bonded routing structures may also be integral and continuous with one another following the bonding process. The additional memory array structure 402 may be attached to the memory array structure 302 without a bond line or with a bond line.

As shown in FIG. 3, within the microelectronic device 100B, the third routing structures 448 (FIG. 2) and the interconnect structures 450 (FIG. 2) may be omitted (e.g., absent) from the additional memory array structure 402, facilitating bonding of some of the additional second routing structures 446 of the additional memory array structure 402 to some of the first routing structures 340 of the memory array structure 302. In additional embodiments, the third routing structures 448 (FIG. 2) and the interconnect structures 450 (FIG. 2) are included within the additional memory array structure 402 of the microelectronic device 100B, and some of the third routing structures 448 (FIG. 2) to some of the first routing structures 340 of the memory array structure 302.

For the B2B arrangement of the control circuitry structure 502 and the additional memory array structure 402 of the microelectronic device 100B, the back side B₅₀₂ of the control circuitry structure 502 may be bonded to the back side B₄₀₂ of the additional memory array structure 402 through dielectric-to-dielectric bonding. For example, the fourth isolation material 504 of the control circuitry structure 502 may be provided in physical contact with the additional third isolation material 442 of the additional memory array structure 402 at an interface, and then the fourth isolation material 504 and the additional third isolation material 442 may be exposed to annealing conditions to form bonds (e.g., dielectric-to-dielectric bonds, such as oxide-to-oxide bonds) between the fourth isolation material 504 and the additional third isolation material 442. By way of non-limiting example, the fourth isolation material 504 and the additional third isolation material 442 may be exposed to a temperature greater than or equal to about 400° C. (e.g., within a range of from about 400° C. to about 800° C., greater than about 800° C.) to form dielectric-to-dielectric bonds between the fourth isolation material 504 and the additional third isolation material 442. In some embodiments, the fourth isolation material 504 and the additional third isolation material 442 are exposed to at least one temperature greater than about 800° C. to form oxide-to-oxide bonds between the fourth isolation material 504 and the additional third isolation material 442. In FIG. 3, the fourth isolation material 504 and the additional third isolation material 442 are distinguished from one another by way of a dashed line representing the interface therebetween prior to bonding. However, the fourth isolation material 504 and the additional third isolation material 442 may be integral and continuous with one another following the bonding process. The control circuitry structure 502 may be attached to the additional memory array structure 402 without a bond line or with a bond line.

Within the WL exit regions 106 of the microelectronic device 100B, the additional WL contact structures 436 may have different configurations (e.g., different sizes, different arrangements relative to other features of the additional memory array structure 402) than those previously described herein with respect to the microelectronic device 100A (FIG. 2). As shown in FIG. 3, the additional WL contact structures 436 may vertically extend from some of the additional first routing structures 440 to the additional WL structures 420. The additional WL contact structures 436 may couple the some of the additional first routing structures 440 to the additional WL structures 420. The additional WL contact structures 436 may individually vertically overlap (e.g., vertically extend through vertical spans of) portions of the additional VC access devices 410 (e.g., the additional second source/drain regions 416 thereof), the additional DL structures 426, the additional DL capping structures 430, and the additional shielding structure 432 of the additional memory array structure 402.

Within the DL exit regions 104, the additional DL contact structures 438 may also have different configurations (e.g., different sizes, different arrangements relative to other features of the additional memory array structure 402) than those previously described herein with respect to the microelectronic device 100A (FIG. 2). As shown in FIG. 3, the additional DL contact structures 438 may vertically extend from some others of the additional first routing structures 440 to the additional DL structures 426. The additional DL contact structures 438 may couple the some others of the additional first routing structures 440 to the additional DL structures 426. The additional DL contact structures 438 may individually vertically overlap (e.g., vertically extend through vertical spans of) the additional DL capping structures 430 and the additional shielding structure 432 of the additional memory array structure 402.

Still referring to FIG. 3, within the microelectronic device 100B, the third contact structures 532 may be formed to vertically extend from some of the fifth routing structures 534 of the control circuitry structure 502 to some of the additional first routing structures 440 of the additional memory array structure 402. The third contact structures 532 may facilitate (in combination with at least the second contact structures 531, the fifth routing structures 534, the additional first routing structures 440, the additional WL contact structures 436, the additional WL structures 420, the additional DL contact structures 438, the additional DL structures 426, the second deep contact structures 435, the additional RDM structures 408, the additional first deep contact structures 444, the additional second routing structures 446, the first routing structures 340, the WL contact structures 336, the WL structures 320, the DL contact structures 338, and the DL structures 326) operable communication between the control logic devices 526 of the control circuitry structure 502 and each of the additional memory cells 424 of the additional memory array structure 402 and the memory cells 324 of the memory array structure 302.

Referring next to FIG. 4, the microelectronic device 100C (and, hence, the microelectronic device 100 (FIG. 1)) may include the carrier structure 202, the memory array structure 302, the additional memory array structure 402, and the control circuitry structure 502 previously described herein with reference to FIG. 2. However, orientations of the additional memory array structure 402 and the memory array structure 302 are vertically inverted relative to those previously described herein with reference to FIG. 2, while maintaining the orientation of the control circuitry structure 502 previously described herein with reference to FIG. 2. The orientation of the additional memory array structure 402 is the same as the orientation of the additional memory array structure 402 for the microelectronic device 100B previously described herein with reference to FIG. 3, but the orientation of the memory array structure 302 is different than the orientation of the memory array structure 302 previously described herein for the microelectronic devices 100A, 100B (FIGS. 2 and 3). As a result, the microelectronic device 100C includes the additional memory array structure 402 vertically overlying and bonded to the memory array structure 302 in a so-called “front-to-front” (F2F) arrangement, and the control circuitry structure 502 vertically overlying and bonded to the additional memory array structure 402 in a B2B arrangement. Namely, as shown in FIG. 4, the front side F₄₀₂ of the additional memory array structure 402 is bonded to the front side F₃₀₂ of the memory array structure 302, and the back side B₅₀₂ of the control circuitry structure 502 is bonded to the back side B₄₀₂ of the additional memory array structure 402. Thus, for the configuration of the microelectronic device 100C, vertical orientations and vertical positions of features of the memory array structure 302 may be vertically inverted relative to vertical orientations and vertical positions of corresponding features of the memory array structure 302 within the configuration of the microelectronic device 100A previously described with reference to FIG. 2; and vertical orientations and vertical positions of features of the additional memory array structure 402 may be the same as vertical orientations and vertical positions of corresponding features of the additional memory array structure 402 within the configuration of the microelectronic device 100B previously described with reference to FIG. 3. Consequently, as described in further detail below, configurations of some of the features of the memory array structure 302 and/or interactions between some of the features of the memory array structure 302 and some other features of the microelectronic device 100C may be modified relative to those of corresponding features within the microelectronic devices 100A, 100B (FIGS. 2 and 3).

For the F2F arrangement of the additional memory array structure 402 and the memory array structure 302 of the microelectronic device 100B, the front side F₄₀₂ of the additional memory array structure 402 may be bonded to the front side F₃₀₂ of the memory array structure 302 through a combination of dielectric-to-dielectric bonding and metal-to-metal bonding. For example, the additional second isolation material 404 and at least some of the additional second routing structures 446 of the additional memory array structure 402 may be provided in physical contact with the second isolation material 304 and at least some of the second routing structures 346 of the memory array structure 302, respectively; and then the additional second isolation material 404, the second isolation material 304, the additional second routing structures 446, and the additional second routing structures 446 may be exposed to annealing conditions to form bonds (e.g., dielectric-to-dielectric bonds, such as oxide-to-oxide bonds) between the additional second isolation material 404 and the second isolation material 304, and additional bonds (e.g., metal-to-metal bonds) between the additional second routing structures 446 and the second routing structures 346. By way of non-limiting example, the additional second isolation material 404, the second isolation material 304, the additional second routing structures 446, and the second routing structures 346 may be exposed to a temperature greater than or equal to about 400° C. (e.g., within a range of from about 400° C. to about 800° C., greater than about 800° C.) to form bonds between the additional second isolation material 404 and the second isolation material 304 and bonds between the additional second routing structures 446 and the second routing structures 346. Bonding the additional second routing structures 446 to the second routing structures 346 may form bonded routing structures individually including a lower portion including an individual second routing structure 346, and an upper portion integral and continuous within the lower portion and including an individual additional second routing structure 446. While FIG. 4 includes a dashed line representing an initial interface location between the additional memory array structure 402 and the memory array structure 302 before the bonding process, the additional second isolation material 404 and the second isolation material 304 may be integral and continuous with one another following the bonding process, and the portions (e.g., upper portion formed from an additional second routing structure 446, lower portion formed from a second routing structure 346) of individual bonded routing structures may also be integral and continuous with one another following the bonding process. The additional memory array structure 402 may be attached to the memory array structure 302 without a bond line or with a bond line.

For the arrangement of the memory array structure 302 and the carrier structure 202 of the microelectronic device 100C, the back side B₃₀₂ of the memory array structure 302 may be bonded to the carrier structure 202 through dielectric-to-dielectric bonding. For example, the third isolation material 342 of the memory array structure 302 may be provided in physical contact with the first isolation material 206 of the carrier structure 202 at an interface, and then the third isolation material 342 and the first isolation material 206 may be exposed to annealing conditions to form bonds (e.g., dielectric-to-dielectric bonds, such as oxide-to-oxide bonds) between the third isolation material 342 and the first isolation material 206. By way of non-limiting example, the third isolation material 342 and the first isolation material 206 may be exposed to a temperature greater than or equal to about 400° C. (e.g., within a range of from about 400° C. to about 800° C., greater than about 800° C.) to form dielectric-to-dielectric bonds between the third isolation material 342 and the first isolation material 206. In some embodiments, the third isolation material 342 and the first isolation material 206 are exposed to at least one temperature greater than about 800° C. to form oxide-to-oxide bonds between the third isolation material 342 and the first isolation material 206. In FIG. 4, the third isolation material 342 and the first isolation material 206 are distinguished from one another by way of a dashed line representing the interface therebetween prior to bonding. However, the third isolation material 342 and the first isolation material 206 may be integral and continuous with one another following the bonding process. The memory array structure 302 may be attached to the carrier structure 202 without a bond line or with a bond line.

Within the WL exit regions 106 of the microelectronic device 100C, the WL contact structures 336 may have different configurations (e.g., different sizes, different arrangements relative to other features of the memory array structure 302) than those previously described herein with respect to the microelectronic device 100A (FIG. 2). As shown in FIG. 4, the WL contact structures 336 may vertically extend from some of the RDM structures 308 to the WL structures 320. The WL contact structures 336 may couple the some of the RDM structures 308 to the WL structures 320. The WL contact structures 336 may individually vertically overlap (e.g., vertically extend through vertical spans of) portions of the VC access devices 310 (e.g., the second source/drain regions 316 thereof) of the memory array structure 302.

Within the DL exit regions 104, the DL contact structures 338 may also have different configurations (e.g., different sizes, different arrangements relative to other features of the memory array structure 302) than those previously described herein with respect to the microelectronic device 100A (FIG. 2). As shown in FIG. 4, the DL contact structures 338 may vertically extend from some others of the RDM structures 308 to the DL structures 326. The DL contact structures 338 may couple the some others of the RDM structures 308 to the DL structures 326. The DL contact structures 338 may individually vertically overlap (e.g., vertically extend through vertical spans of) portions of the VC access devices 310, such as each of the first source/drain region 314, the channel region 318, and the second source/drain region 316 of respective ones of the VC access devices 310.

Still referring to FIG. 4, within the DL exit regions 104 and/or the WL exit region 106, the memory array structure 302 of the microelectronic device 100C may include a different (e.g., relatively greater) quantity of the first deep contact structures 344 and compared to a quantity of the first deep contact structures 344 within the memory array structure 302 of the microelectronic devices 100A, 100B (FIGS. 2 and 3). Some of the additional first deep contact structures 444, in combination with other features (e.g., the WL contact structures 336, some of the RDM structures 308, some of the second routing structures 346) of the memory array structure 302, facilitate signal routing paths extending to the WL structures 320 of the memory array structure 302. Some others of the first deep contact structures 344, in combination with further features (e.g., the DL contact structures 338, some others of the RDM structures 308, some others of the second routing structures 346) of the memory array structure 302, facilitate signal routing paths extending to the DL structures 326 of the memory array structure 302. Still others of the first deep contact structures 344, in combination with still other features of the memory array structure 302, respectively facilitate other signal routing paths extending within the memory array structure 302 (e.g., to the shielding structure 332).

The memory array structure 302 may further include one or more shielding contact structures 337 coupled to the shielding structure 332 and individually configured, in combination with further features (e.g., routing structures, contact structures, devices) of the microelectronic device 100C, to facilitate one or more signal routing paths to the shielding structure 332. The signal routing path(s) may, for example, be employed to bias the shielding structure 332, as desired. As shown in FIG. 4, within the memory array structure 302, the shielding contact structures 337 may vertically extend from the RDM structures 308 to the shielding structure 332. The shielding contact structures 337 may respectively vertically overlap (e.g., vertically extend through vertical spans of) portions of the VC access devices 310 (e.g., the first source/drain region 314, the channel region 318, and the second source/drain region 316 of respective ones of the VC access devices 310), the WL structures 320, the DL structures 326, and the DL capping structures 330.

It will be understood that shielding contact structures 337 may be included in the memory array structure 302 of any of the microelectronic devices 100A, 100B, 100C, 100D described herein with reference to FIGS. 2 through 5 (and, hence, within the microelectronic device 100 (FIG. 1)). While configurations of the shielding contact structures 337 within the memory array structure 302 may be modified based, at least in part, on an orientation of the memory array structure 302, the function of the shielding contact structures 337 may remain substantially the same. In addition, it will be understood that additional shielding contact structures, corresponding to the shielding contact structures 337, may be included in the additional memory array structure 402 of any of the microelectronic devices 100A, 100B, 100C, 100D described herein with reference to FIGS. 2 through 5 (and, hence, within the microelectronic device 100 (FIG. 1)). While configurations of such additional shielding contact structures within the additional memory array structure 402 may be modified based, at least in part, on an orientation of the additional memory array structure 402, the function of the additional shielding contact structures may be substantially the same as that described herein with reference to the shielding contact structures 337. Namely, the additional shielding contact structures may be configured, in conjunction with other features of the respective microelectronic device 100A, 100B, 100C, 100D (FIGS. 2 through 5), to facilitate one or more signal routing paths to the additional shielding structure 432. The signal routing path(s) may, for example, be employed to bias the additional shielding structure 432, as desired.

Still referring to FIG. 4, within the microelectronic device 100C, the second contact structures 531, the fifth routing structures 534, the third contact structures 532, the additional first routing structures 440, the additional WL contact structures 436, the additional WL structures 420, the additional DL contact structures 438, the additional DL structures 426, the second deep contact structures 435, the additional RDM structures 408, the additional first deep contact structures 444, the additional second routing structures 446, the second routing structures 346, the additional first deep contact structures 444, RDM structures 308, the WL contact structures 336, the WL structures 320, the DL contact structures 338, and the DL structures 326 may, in combination, facilitate operable communication between the control logic devices 526 of the control circuitry structure 502 and each of the additional memory cells 424 of the additional memory array structure 402 and the memory cells 324 of the memory array structure 302.

Referring next to FIG. 5, the microelectronic device 100D (and, hence, the microelectronic device 100 (FIG. 1)) may include the carrier structure 202, the memory array structure 302, the additional memory array structure 402, and the control circuitry structure 502 previously described herein with reference to FIG. 2. However, the control circuitry structure 502 may be positioned vertically between the memory array structure 302 and the additional memory array structure 402, and an orientation of the control circuitry structure 502 may be vertically inverted relative to that previously described herein with reference to FIG. 2. The orientations of the memory array structure 302 and the additional memory array structure 402 may be the same as those previously described herein with reference to FIG. 2. As a result, the microelectronic device 100D includes the control circuitry structure 502 overlying and bonded to the memory array structure 302 in a F2B arrangement, and the additional memory array structure 402 vertically overlying and bonded to the control circuitry structure 502 in a B2B arrangement. Namely, as shown in FIG. 4, the front side F₅₀₂ of the control circuitry structure 502 is bonded to the back side B₃₀₂ of the memory array structure 302, and the back side B₄₀₂ of the additional memory array structure 402 is bonded to the back side B₅₀₂ of the control circuitry structure 502. Thus, for the configuration of the microelectronic device 100D, vertical orientations and vertical positions of features of the control circuitry structure 502 may be vertically inverted relative to vertical orientations and vertical positions of corresponding features of the control circuitry structure 502 within the configuration of the microelectronic device 100A previously described with reference to FIG. 2. Consequently, as described in further detail below, configurations of some of the features of the control circuitry structure 502 and the additional memory array structure 402 thereover, and/or interactions between some of the features and some other features of the microelectronic device 100D may be modified relative to those of corresponding features within the microelectronic device 100A (FIG. 2).

For the F2B arrangement of the control circuitry structure 502 and the memory array structure 302 of the microelectronic device 100D, the front side F₅₀₂ of the control circuitry structure 502 may be bonded to the back side B₃₀₂ of the memory array structure 302 through a combination of dielectric-to-dielectric bonding and metal-to-metal bonding. For example, the fifth isolation material 536 and at least some of the fifth routing structures 534 of the control circuitry structure 502 may be provided in physical contact with the third isolation material 342 and at least some of the first routing structures 340 of the memory array structure 302, respectively; and then the fifth isolation material 536, the third isolation material 342, the fifth routing structures 534, and the first routing structures 340 may be exposed to annealing conditions to form bonds (e.g., dielectric-to-dielectric bonds, such as oxide-to-oxide bonds) between the fifth isolation material 536 and the third isolation material 342, and additional bonds (e.g., metal-to-metal bonds) between the fifth routing structures 534 and the first routing structures 340. By way of non-limiting example, the fifth isolation material 536, the third isolation material 342, the fifth routing structures 534, and the first routing structures 340 may be exposed to a temperature greater than or equal to about 400° C. (e.g., within a range of from about 400° C. to about 800° C., greater than about 800° C.) to form bonds between the fifth isolation material 536 and the third isolation material 342 and bonds between the fifth routing structures 534 and the first routing structures 340. Bonding the fifth routing structures 534 to the first routing structures 340 may form bonded routing structures individually including a lower portion including an individual first routing structure 340, and an upper portion integral and continuous within the lower portion and including an individual fifth routing structure 534. While FIG. 5 includes a dashed line representing an initial interface location between the control circuitry structure 502 and the memory array structure 302 before the bonding process, the fifth isolation material 536 and the third isolation material 342 may be integral and continuous with one another following the bonding process, and the portions (e.g., upper portion formed from a fifth routing structure 534, lower portion formed from a first routing structure 340) of individual bonded routing structures may also be integral and continuous with one another following the bonding process. The control circuitry structure 502 may be attached to the memory array structure 302 without a bond line or with a bond line.

As shown in FIG. 5, as a result of the vertical position and orientation of the control circuitry structure 502 within the of the microelectronic device 100D, the control circuitry structure 502 may further include sixth routing structures 538 and seventh routing structures 540. The sixth routing structures 538 and the seventh routing structures 540 may respectively be vertically positioned relatively closer to the back side B₅₀₂ of the control circuitry structure 502 (and hence, relatively closer to the additional memory array structure 402) than are the fourth routing structures 530 and the fifth routing structures 534. For example, the sixth routing structures 538 may vertically overlie the transistors 510 of the control circuitry structure 502, and the seventh routing structures 540 may vertically overlie the sixth routing structures 538. Furthermore, the control circuitry structure 502 may also include fourth contact structures 533 and fifth contact structures 542 operatively associated with the sixth routing structures 538 and the seventh routing structures 540 so as to facilitate desirable signal routing paths (e.g., from the control logic devices 526 to the additional memory cell 424 and/or the memory cells 324) for the microelectronic device 100D. In some embodiments, the fourth contact structures 533 are formed to respectively vertically extend from the fourth routing structures 530 to the sixth routing structures 538 or the seventh routing structures 540, and the fifth contact structures 542 are formed to respectively vertically extend from the sixth routing structures 538 to the seventh routing structures 540. In addition, as shown in FIG. 5, the third contact structures 532 may be formed to vertically extend from the fifth routing structures 534 to the sixth routing structures 538. The sixth routing structures 538, the seventh routing structures 540, the fourth contact structures 533, and the fifth contact structures 542 may respectively be formed of and include conductive material. In some embodiments, the sixth routing structures 538, the seventh routing structures 540, the fourth contact structures 533, and the fifth contact structures 542 are individually formed of and include one or more of W, Ru, Mo, and TiN.

For the B2B arrangement of the additional memory array structure 402 and control circuitry structure 502 of the microelectronic device 100D, the back side B₄₀₂ of the additional memory array structure 402 may be bonded to the back side B₅₀₂ of the control circuitry structure 502 through a combination of dielectric-to-dielectric bonding and metal-to-metal bonding. For example, the additional third isolation material 442 and at least some of the additional first routing structures 440 of the additional memory array structure 402 may be provided in physical contact with the fourth isolation material 504 and at least some of the seventh routing structures 540 of the control circuitry structure 502, respectively; and then the additional third isolation material 442, the fourth isolation material 504, the additional first routing structures 440, and the seventh routing structures 540 may be exposed to annealing conditions to form bonds (e.g., dielectric-to-dielectric bonds, such as oxide-to-oxide bonds) between the additional third isolation material 442 and the fourth isolation material 504, and additional bonds (e.g., metal-to-metal bonds) between the additional first routing structures 440 and the seventh routing structures 540. By way of non-limiting example, the additional third isolation material 442, the fourth isolation material 504, the additional first routing structures 440, and the seventh routing structures 540 may be exposed to a temperature greater than or equal to about 400° C. (e.g., within a range of from about 400° C. to about 800° C., greater than about 800° C.) to form bonds between the additional third isolation material 442 and the fourth isolation material 504 and bonds between the additional first routing structures 440 and the seventh routing structures 540. Bonding the additional first routing structures 440 to the seventh routing structures 540 may form bonded routing structures individually including a lower portion including an individual seventh routing structure 540, and an upper portion integral and continuous within the lower portion and including an individual additional first routing structure 440. While FIG. 5 includes a dashed line representing an initial interface location between the additional memory array structure 402 and the control circuitry structure 502 before the bonding process, the additional third isolation material 442 and the fourth isolation material 504 may be integral and continuous with one another following the bonding process, and the portions (e.g., upper portion formed from an additional first routing structure 440, a lower portion formed from a seventh routing structure 540) of individual bonded routing structures may also be integral and continuous with one another following the bonding process. The additional memory array structure 402 may be attached to the control circuitry structure 502 without a bond line or with a bond line.

Within the WL exit regions 106 of the microelectronic device 100D, the additional WL contact structures 436 of the additional memory array structure 402 may have different configurations (e.g., different sizes, different arrangements relative to other features of the additional memory array structure 402) than those previously described herein with respect to the microelectronic device 100A (FIG. 2). As shown in FIG. 5, the additional WL contact structures 436 may vertically extend from the additional WL structures 420 to some of the additional first routing structures 440. The additional WL contact structures 436 may couple the additional WL structures 420 to the some of the additional first routing structures 440. The additional WL contact structures 436 may individually vertically overlap (e.g., vertically extend through vertical spans of) portions of the additional VC access devices 410 (e.g., the additional second source/drain regions 416 thereof) of the additional memory array structure 402.

Within the DL exit regions 104 of the microelectronic device 100D, the additional DL contact structures 438 of the additional memory array structure 402 may have different configurations (e.g., different sizes, different arrangements relative to other features of the additional memory array structure 402) than those previously described herein with respect to the microelectronic device 100A (FIG. 2). As shown in FIG. 5, the additional DL contact structures 438 may vertically extend from the additional DL structures 426 to some others of the additional first routing structures 440. The additional DL contact structures 438 may couple the additional DL structures 426 to the some others of the additional first routing structures 440. The additional DL contact structures 438 may individually vertically overlap (e.g., vertically extend through vertical spans of) the additional DL capping structures 430 and the additional shielding structure 432 of the additional memory array structure 402.

Still referring to FIG. 5, within the microelectronic device 100D, the second contact structures 531, the fifth routing structures 534, the third contact structures 532, the fourth contact structures 533, the sixth routing structures 538, the fifth contact structures 542, the seventh routing structures 540, the additional first routing structures 440, the additional WL contact structures 436, the additional WL structures 420, the additional DL contact structures 438, the additional DL structures 426, the second deep contact structures 435, the first routing structures 340, the WL contact structures 336, the WL structures 320, the DL contact structures 338, and the DL structures 326 may, in combination, facilitate operable communication between the control logic devices 526 of the control circuitry structure 502 and each of the additional memory cells 424 of the additional memory array structure 402 and the memory cells 324 of the memory array structure 302.

With collective reference to FIGS. 1 through 5, the configurations of the microelectronic devices 100A, 100B, 100C, 100D (and, hence, the microelectronic device 100) of the disclosure may facilitate enhanced device performance (e.g., speed, data transfer rates, power consumption) relative to conventional microelectronic device configurations. For example, the configurations of the memory array structure 302, the additional memory array structure 402, and the control circuitry structure 502 individually and relative to one another may facilitate enhanced array efficiency, and may also provide enhanced alignment margin as compared to conventional methods. Moreover, structures, devices, and methods described above with reference to FIGS. 1 through 5 may resolve limitations on array (e.g., memory cell array) configurations, control logic device configurations, and associated device performance that may otherwise result from thermal budget constraints imposed by the formation and/or processing of arrays (e.g., memory cell arrays) of a microelectronic device.

Thus, in accordance with embodiments of the disclosure, a microelectronic device includes a memory array structure, an additional memory array structure, and a control circuitry structure. The memory array structure includes memory cells respectively including a vertical channel access device and a storage node device coupled to the vertical channel access device. The additional memory array structure vertically overlies the memory array structure and includes additional memory cells respectively including an additional vertical channel access device and an additional storage node device coupled to the additional vertical channel access device. The control circuitry structure vertically overlies and is bonded to one or more of the memory array structure and the additional memory array structure. The control circuitry structure includes control logic circuitry coupled to the memory cells of the memory array structure and the additional memory cells of the additional memory array structure.

Furthermore, in accordance with embodiments of the disclosure, a memory device includes a memory array structure, an additional memory array structure vertically overlying and bonded to the memory array, and a control circuitry structure vertically overlying and bonded to the additional memory array structure. The memory array structure includes dynamic random access memory (DRAM) cells therein. The DRAM cells respectively include a vertical channel access device and a capacitor vertically offset from and coupled to the vertical channel access device. The additional memory array structure includes additional DRAM cells therein. The additional DRAM cells respectively include an additional vertical channel access device and an additional capacitor vertically offset from and coupled to the additional vertical channel access device. The control circuitry structure includes control logic devices coupled to the DRAM cells of the memory array structure and the additional DRAM cells of the additional memory array structure.

Furthermore, in accordance with embodiments of the disclosure, a memory device includes a memory array structure, a control circuitry structure vertically overlying and bonded to the memory array structure, and an additional memory array structure vertically overlying and bonded to the control circuitry structure. The memory array structure includes dynamic random access memory (DRAM) cells therein. The DRAM cells respectively include a vertical channel access device and a capacitor vertically offset from and coupled to the vertical channel access device. The control circuitry structure includes control logic devices coupled to the DRAM cells of the memory array structure. The additional memory array structure has additional DRAM cells therein. The additional DRAM cells are coupled to the control logic devices of the control circuitry structure and respectively include an additional vertical channel access device and an additional capacitor vertically offset from and coupled to the additional vertical channel access device.

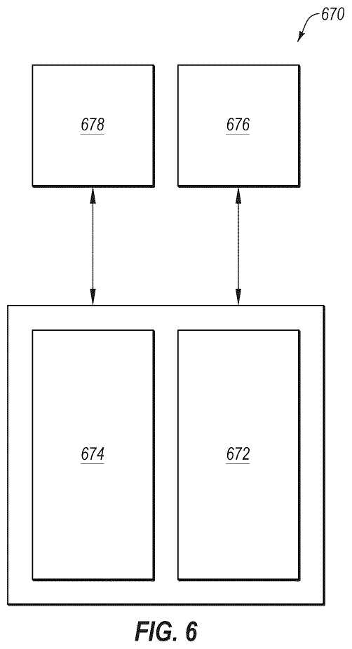

Microelectronic devices (e.g., the microelectronic devices 100, 100A, 100B, 100C, 100D (FIGS. 1 through 5)) in accordance with embodiments of the disclosure may be used in embodiments of electronic systems of the disclosure. For example, FIG. 6 is a block diagram illustrating an electronic system 670 according to embodiments of disclosure. The electronic system 670 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 670 includes at least one memory device 672. The memory device 672 may comprise, for example, a microelectronic device (e.g., one of the microelectronic devices 100A, 100B, 100C, 100D (FIGS. 2 through 5)) previously described herein. The electronic system 670 may further include at least one electronic signal processor device 674 (often referred to as a “microprocessor”). The electronic signal processor device 674 may, optionally, comprise a microelectronic device (e.g., one of the microelectronic devices 100A, 100B, 100C, 100D (FIGS. 2 through 5)) previously described herein. While the memory device 672 and the electronic signal processor device 674 are depicted as two (2) separate devices in FIG. 6, in additional embodiments, a single (e.g., only one) memory/processor device having the functionalities of the memory device 672 and the electronic signal processor device 674 is included in the electronic system 670. In such embodiments, the memory/processor device may include a microelectronic device (e.g., one of the microelectronic devices 100A, 100B, 100C, 100D (FIGS. 2 through 5)) previously described herein. The electronic system 670 may further include one or more input devices 676 for inputting information into the electronic system 670 by a user, such as, for example, a mouse or other pointing device, a keyboard, a touchpad, a button, or a control panel. The electronic system 670 may further include one or more output devices 678 for outputting information (e.g., visual or audio output) to a user such as, for example, a monitor, a display, a printer, an audio output jack, a speaker, etc. In some embodiments, the input device 676 and the output device 678 comprise a single touchscreen device that can be used both to input information to the electronic system 670 and to output visual information to a user. The input device 676 and the output device 678 may communicate electrically with one or more of the memory device 672 and the electronic signal processor device 674.

The structures, devices, and methods of the disclosure advantageously facilitate one or more of improved microelectronic device performance, reduced costs (e.g., manufacturing costs, material costs), increased miniaturization of components, and greater packaging density as compared to conventional structures, conventional devices, and conventional methods. The structures, devices, and methods of the disclosure may also improve scalability, efficiency, and simplicity as compared to conventional structures, conventional devices, and conventional methods.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalent. For example, elements and features disclosed in relation to one embodiment may be combined with elements and features disclosed in relation to other embodiments of the disclosure.

What is claimed is:

1. A microelectronic device, comprising:
a memory array structure including memory cells respectively comprising a vertical channel access device and a storage node device coupled to the vertical channel access device;
an additional memory array structure vertically overlying the memory array structure and including additional memory cells respectively comprising an additional vertical channel access device and an additional storage node device coupled to the additional vertical channel access device; and
a control circuitry structure vertically overlying and bonded to one or more of the memory array structure and the additional memory array structure, the control circuitry structure comprising control logic circuitry coupled to the memory cells of the memory array structure and the additional memory cells of the additional memory array structure.

2. The microelectronic device of claim 1, wherein:
the vertical channel access device of respective ones of the memory cells comprises:
two source/drain regions;
a channel region vertically interposed between the two source/drain regions; and
a gate electrode horizontally offset from and vertically overlapping the channel region; and
the additional vertical channel access device of respective ones of the additional memory cells comprises:
two additional source/drain regions;
an additional channel region vertically interposed between the two additional source/drain regions; and
an additional gate electrode horizontal offset from and vertically overlapping the additional channel region.

3. The microelectronic device of claim 2, wherein:
the additional memory array structure is bonded to the memory array structure; and
the control circuitry structure vertically overlies and is bonded to the additional memory array structure.

4. The microelectronic device of claim 3, wherein:
the memory cells of the memory array structure respectively comprise the vertical channel access device vertically over and coupled to the storage node device;
the additional memory cells of the additional memory array structure respectively comprise the additional vertical channel access device vertically under and coupled to the additional storage node device; and
the control logic circuitry of the control circuitry structure comprises transistors respectively comprising a further gate electrode vertically overlying and horizontally overlapping a further channel region.

5. The microelectronic device of claim 3, wherein:
the memory cells of the memory array structure respectively comprise the vertical channel access device vertically over and coupled to the storage node device;
the additional memory cells of the additional memory array structure respectively comprise the additional vertical channel access device vertically over and coupled to the additional storage node device; and
the control logic circuitry of the control circuitry structure comprises transistors respectively comprising a further gate electrode vertically overlying and horizontally overlapping a further channel region.

6. The microelectronic device of claim 3, wherein:
the memory cells of the memory array structure respectively comprise the vertical channel access device vertically under and coupled to the storage node device;
the additional memory cells of the additional memory array structure respectively comprise the additional vertical channel access device vertically over and coupled to the additional storage node device; and
the control logic circuitry of the control circuitry structure comprises transistors respectively comprising a further gate electrode vertically overlying and horizontally overlapping a further channel region.

7. The microelectronic device of claim 3, wherein:
the additional memory array structure is bonded to the memory array structure through a combination of dielectric-to-dielectric bonds and metal-to-metal bonds; and
the control circuitry structure is bonded to the additional memory array structure through additional dielectric-to-dielectric bonds.

8. The microelectronic device of claim 2, wherein:
the control circuitry structure vertically overlies and is bonded to the memory array structure; and
the additional memory array structure vertically overlies and is bonded to the control circuitry structure.

9. The microelectronic device of claim 8, wherein:
the memory cells of the memory array structure respectively comprise the vertical channel access device vertically over and coupled to the storage node device;
the control logic circuitry of the control circuitry structure comprises transistors respectively comprising a further gate electrode vertically underlying and horizontally overlapping a further channel region; and
the additional memory cells of the additional memory array structure respectively comprise the additional vertical channel access device vertically under and coupled to the additional storage node device.

10. The microelectronic device of claim 9, wherein:
the control circuitry structure is bonded to the memory array structure through a combination of dielectric-to-dielectric bonds and metal-to-metal bonds; and
the control circuitry structure is bonded to the additional memory array structure through a combination of additional dielectric-to-dielectric bonds and additional metal-to-metal bonds.

11. A memory device, comprising:
a memory array structure including dynamic random access memory (DRAM) cells therein, the DRAM cells respectively comprising a vertical channel access device and a capacitor vertically offset from and coupled to the vertical channel access device;
an additional memory array structure vertically overlying and bonded to the memory array structure and having additional DRAM cells therein, the additional DRAM cells respectively comprising an additional vertical channel access device and an additional capacitor vertically offset from and coupled to the additional vertical channel access device; and
a control circuitry structure vertically overlying and bonded to the additional memory array structure, the control circuitry structure comprising control logic devices coupled to the DRAM cells of the memory array structure and the additional DRAM cells of the additional memory array structure.

12. The memory device of claim 11, wherein:
the additional memory array structure is bonded to the memory array structure in a back-to-back arrangement, such that:
for respective ones of the DRAM cells, the capacitor thereof vertically underlies the vertical channel access device thereof; and
for respective ones of the additional DRAM cells, the additional capacitor thereof vertically overlies the additional vertical channel access device thereof; and
the control circuitry structure is bonded to the additional memory array structure in a back-to-front arrangement, such that transistors of the control logic devices respectively comprise a channel region vertically underlying and horizontally overlapping a gate electrode.

13. The memory device of claim 11, wherein:
the additional memory array structure is bonded to the memory array structure in a front-to-back arrangement, such that:
for respective ones of the DRAM cells, the capacitor thereof vertically underlies the vertical channel access device thereof; and
for respective ones of the additional DRAM cells, the additional capacitor thereof vertically underlies the additional vertical channel access device thereof; and
the control circuitry structure is bonded to the additional memory array structure in a back-to-back arrangement, such that transistors of the control logic devices respectively comprise a channel region vertically underlying and horizontally overlapping a gate electrode.

14. The memory device of claim 11, wherein:
the additional memory array structure is bonded to the memory array structure in a front-to-front arrangement, such that:
for respective ones of the DRAM cells, the capacitor thereof vertically overlies the vertical channel access device thereof; and
for respective ones of the additional DRAM cells, the additional capacitor thereof vertically underlies the additional vertical channel access device thereof; and
the control circuitry structure is bonded to the additional memory array structure in a back-to-back arrangement, such that transistors of the control logic devices respectively comprising channel region vertically underlying and horizontally overlapping a gate electrode.

15. The memory device of claim 11, wherein:
the additional memory array structure and the memory array structure are bonded to one another through a combination of dielectric-to-dielectric bonds and metal-to-metal bonds; and
the control circuitry structure and the additional memory array structure are bonded to one another through additional dielectric-to-dielectric bonds.

16. A memory device, comprising:
a memory array structure including dynamic random access memory (DRAM) cells therein, the DRAM cells respectively comprising a vertical channel access device and a capacitor vertically offset from and coupled to the vertical channel access device;
a control circuitry structure vertically overlying and bonded to the memory array structure, the control circuitry structure comprising control logic devices coupled to the DRAM cells of the memory array structure; and
an additional memory array structure vertically overlying and bonded to the control circuitry structure and having additional DRAM cells therein, the additional DRAM cells coupled to the control logic devices of the control circuitry structure and respectively comprising an additional vertical channel access device and an additional capacitor vertically offset from and coupled to the additional vertical channel access device.

17. The memory device of claim 16, wherein:
the control circuitry structure is bonded to the memory array structure in a front-to-back arrangement, such that:
transistors of the control logic devices respectively comprise a channel region vertically overlying and horizontally overlapping a gate electrode;
for respective ones of the DRAM cells, the capacitor thereof vertically underlies the vertical channel access device thereof; and
the additional memory array structure is bonded to the control circuitry structure is bonded in a back-to-back arrangement, such that:
for respective ones of the additional DRAM cells, the additional capacitor thereof vertically overlies the additional vertical channel access device thereof.

18. The memory device of claim 16, wherein:
the control circuitry structure and the memory array structure are bonded to one another through a combination of dielectric-to-dielectric bonds and metal-to-metal bonds; and
the control circuitry structure and the additional memory array structure are bonded to one another through a combination of additional dielectric-to-dielectric bonds and additional metal-to-metal bonds.

19. The memory device of claim 16, wherein:
the memory array structure further comprises:
digit line structures vertically overlying and coupled to the DRAM cells; and
a shielding structure at least partially vertically overlying and horizontally overlapping the digit line structures; and
the additional memory array structure further comprises:
additional digit line structures vertically underlying and coupled to the additional DRAM cells; and
an additional shielding structure at least partially vertically underlying and horizontally overlapping the additional digit line structures.

20. The memory device of claim 19, wherein:
the shielding structure comprises projections respectively vertically overlapping and horizontally interposed between two of the digit line structures horizontally neighboring one another; and
the additional shielding structure comprises additional projections respectively vertically overlapping and horizontally interposed between two of the additional digit line structures horizontally neighboring one another.
